(19) United States
(12) Patent Application Publication
(10) Pub. No.: US 2010/0255303 A1
(43) Pub. Date: Oct. 7, 2010

(54) MULTIFUNCTIONAL COMPOSITES BASED ON COATED NANOSTRUCTURES

(75) Inventors: Brian L. Wardle, Lexington, MA (US); Hulya Cebeci, Somerville, MA (US); Sreeram Vaddiraju, Cambridge, MA (US); Karen K. Gleason, Cambridge, MA (US)

Correspondence Address: WOLF GREENFIELD & SACKS, P.C., 600 ATLANTIC AVENUE, BOSTON, MA, 02210-2206, US

(73) Assignee: Massachusetts Institute of Technology, Cambridge, MA (US)

(21) Appl. No.: 12/630,289

(22) Filed: Dec. 3, 2009

Related U.S. Application Data
(60) Provisional application No. 61/119,673, filed on Dec. 3, 2008.

(51) Int. Cl. D02G 3/36; C23C 16/44

(52) U.S. Cl. 428/378; 427/255.6; 977/778

(57) ABSTRACT

Processing of nanostructures, composite materials comprising nanostructures, and related systems and methods are described. In some embodiments, conformal coatings are applied to nanostructures.

### RELATED APPLICATIONS

This application claims the benefit of U.S. Provisional Patent Application Ser. No. 61/119,673, filed on Dec. 3, 2008, entitled “Multifunctional Composites Based on Coated Nanostructures,” by Wardle. et al., which is incorporated herein by reference in its entirety for all purposes.

### FIELD OF THE INVENTION

The present invention generally relates to the processing of nanostructures, composite materials comprising nanostructures, and related systems and methods. In some embodiments, conformal coatings are applied to the nanostructures.

### BACKGROUND

Composites are heterogeneous structures comprising two or more components, the combination taking advantage of the individual properties of each component as well as synergistic effects if relevant. Advanced composites refer to a class of materials in which engineered (e.g., man-made) fibers are embedded in a matrix, typically with the fibers being aligned or even woven such that a material with directional (anisotropic) properties is formed. Nanostructures such as carbon nanotubes (CNTs) are envisioned as constituents in these applications due to their attractive multifunctional (mechanical and non-mechanical) properties. Typically, bulk nanopowders of nanostructures are employed for the fabrication of composites.

Coated nanostructures can exhibit enhanced properties, such as electrical or mechanical properties. Previous coating methods for CNT arrays have resulted in materials plagued by non-uniformities in composition, often attributed to agglomeration of nanotubes during coating. Also, previous coating methods have been shown to alter the morphology and/or alignment of the nanotubes, and have also led to shrinkage of CNT bundles. The random orientation of the resulting nanostructures often makes it difficult to study directionally dependent properties of the composites. In addition, uniform coating methods for nanostructures having high aspect ratio have not been shown.

Accordingly, improved materials and methods are needed.

### SUMMARY OF THE INVENTION

The present invention relates generally to the processing of nanostructures, composite materials comprising nanostructures, and related articles and methods. The subject matter of the present invention involves, in some cases, interrelated products, alternative solutions to a particular problem, and/or a plurality of different uses of one or more systems and/or articles.

The present invention relates to articles comprising a plurality of nanostructures at least some of which have a length of at least 10 microns, the long axes of the nanostructures being substantially aligned relative to each other; and a conformal polymer coating attached to the nanostructures, wherein the nanostructures have a morphology substantially similar to a morphology of essentially identical nanostructures lacking the polymer coating, under essentially identical conditions.

The present invention also relates to articles comprising a plurality of nanostructures at least some of which have a diameter less than 20 nm, the long axes of the nanostructures being substantially aligned relative to each other; and a conformal polymer coating attached to the nanostructures, wherein the nanostructures have a morphology substantially similar to a morphology of essentially identical nanostructures lacking the polymer coating, under essentially identical conditions.

The present invention relates to articles comprising a plurality of nanostructures, wherein the long axes of the nanostructures are substantially aligned relative to each other and the nanostructures have a density of at least 10⁸/cm²; and a conformal polymer coating attached to the nanostructures, wherein the nanostructures have a morphology substantially similar to a morphology of essentially identical nanostructures lacking the polymer coating, under essentially identical conditions.

The present invention also provides methods of producing a material comprising providing a plurality of nanostructures at least some of which have a length of at least 10 microns, the long axes of the nanostructures being substantially aligned relative to each other; and forming, on the plurality of nanostructures, a conformal coating comprising a polymeric material.

Other aspects, embodiments and features of the invention will become apparent from the following detailed description when considered in conjunction with the accompanying drawings. The accompanying figures are schematic and are not intended to be drawn to scale. For purposes of clarity, not every component is labeled in every figure, nor is every component of each embodiment of the invention shown where illustration is not necessary to allow those of ordinary skill in the art to understand the invention. All patent applications and patents incorporated herein by reference are incorporated by reference in their entirety. In case of conflict, the present specification, including definitions, will control.

### BRIEF DESCRIPTION OF THE DRAWINGS

Non-limiting embodiments of the present invention will be described by way of example with reference to the accompanying figures, which are schematic and are not intended to be drawn to scale. In the figures, each identical or nearly identical component illustrated is typically represented by a single numeral. For purposes of clarity, not every component is labeled in every figure, nor is every component of each embodiment of the invention shown where illustration is not necessary to allow those of ordinary skill in the art to understand the invention. In the figures:

FIG. 1A shows an illustration of a two-phase article, according to one embodiment of the invention.

FIG. 1B shows an illustration of a three-phase article comprising a fiber substrate, according to one embodiment of the invention.

FIG. 2 shows an illustration of a three-phase article, according to one embodiment of the invention.

FIG. 3 shows a scanning electron (SEM) image of PEDOT-coated carbon nanotubes (cross-sectional view).

FIG. 4 shows a high magnification SEM image of PEDOT-coated carbon nanotubes.

FIG. 5 shows an image profile of conformally coated nanotubes using Energy Dispersive Spectroscopy (EDS).

FIG. 6 shows an EDS profile of the sulfur content for PEDOT-coated carbon nanotubes.

FIG. 7 shows a transmission electron micrograph (TEM) of PEDOT-coated carbon nanotubes.

FIG. 8 shows a micrograph of carbon nanotubes after PEDOT coating and a higher magnification image of a single carbon nanotube coated with PEDOT (inset).

FIG. 9 shows a micrograph of PEDOT dots on a silicon substrate after removal of carbon nanotubes.

FIG. 10 shows FTIR spectra of a silicon substrate after removal of carbon nanotubes and a standard spectrum of oCVD deposited PEDOT film.

FIG. 11A shows a schematic representation of a two-phase composite, with the radial direction indicated by a block arrow.

FIG. 11B shows a schematic representation of a three-phase composite, with the radial direction indicated by a block arrow.

FIG. 12A shows an Arrhenius plot of conductivity as a function of temperature for two-phase and three-phase composites in the radial direction.

FIG. 12B shows a plot of activation energies needed for charge conduction in two- and three-phase composites as a function of volume fraction of nanostructures within the composites, wherein the introduction of a conformal conducting polymer coating is observed to reduce the activation energy needed for conduction in the radial direction.

FIG. 12C shows a plot of resistivity of various composites as a function of temperature in the radial direction.

FIG. 13 shows a table of activation energy required for charge conduction along the radial direction and axial direction for nanotube-containing composites as a function of intertube distance between conformally coated nanotubes.

FIG. 14A shows a schematic representation of a two-phase composite with the axial direction indicated by a block arrow.

FIG. 14B shows a schematic representation of a three-phase composite, with the axial direction indicated by a block arrow.

FIG. 15A shows an Arrhenius plot of conductivity as a function of temperature for two-phase and three-phase composites in the axial direction.

FIG. 15B shows a plot of activation energies needed for charge conduction in two- and three-phase composites as a function of volume fraction of nanostructures within the composites, wherein the introduction of a conformal conducting polymer coating is observed to have negligible effect on the activation energy needed for conduction in the axial direction.

FIG. 15C shows a plot of resistivity of various composites as a function of temperature in the axial direction.

FIG. 16 shows micrographs of cross-sections of three-phase composites.

FIG. 17 shows images of contact angle measurements of water droplets on various surfaces including (i) uncoated carbon nanotubes, (ii) PEDOT-coated carbon nanotubes, and (iii) PEDOT.

FIG. 18A shows an SEM image of an Al cloth with carbon nanotubes without a conformal polymer coating.

FIG. 18B shows SEM images of an Al cloth with carbon nanotubes prior to to conformally coating with PEDOT (left images) and after to conformally coating with PEDOT (right images).

FIG. 19 shows a schematic representation of a method used to fabricate composite articles, according to one embodiment of the invention.

### DETAILED DESCRIPTION

Generally, the present invention relates to materials that include nanostructures (e.g., nanotubes) and various methods for the production of such materials. In some cases, formation of a conformal coating (e.g., polymer coating) on the nanostructures may produce a material having enhanced mechanical, thermal, optical, and/or electrical properties. The nanostructures may be fabricated, for example, by growing the nanostructures on the surface of a substrate, such that their long axes are aligned and non-parallel (e.g., substantially perpendicular) to the substrate surface, followed by formation of a conformal coating on the nanostructures. In some cases, the conformal coating may include a conducting polymer. The materials may be further processed to incorporate additional components, including thermoset or thermoplastic polymers. Materials and articles described herein may exhibit high mechanical strength, anisotropic properties, such as directional dependent electrical properties, and may be useful in various applications, such as microelectronics, capacitors (e.g., ultracapacitors), advanced aerospace composites, sensors (e.g., chemical sensors, biological sensors), electromechanical probes, electrodes (e.g., nanostructured electrodes for optoelectronic devices including solar cells), batteries, filters (e.g., nanoscale filters, filters for bacteria (e.g., E. coli)), and the like.

An advantageous feature of some embodiments is the ability to form conformal coatings on materials (e.g., nanostructures) with little or substantially no change in the alignment, morphology and/or other characteristics of the underlying material. As used herein, a “conformal” coating refers to a coating formed on and attached or adhered to a material, wherein the coating physically matches the exterior contour of the surface area of the underlying material and the coating does not substantially change the morphology of the underlying material. That is, the coated material has a morphology that is essentially the same as the morphology of an essentially identical material lacking the polymer coating, under essentially identical conditions. It should be understood that the to conformal coating may uniformly increase one or more dimensions (e.g., thickness) of the material, however, the overall morphology of the material remains essentially unchanged. For example, a conformal coating on a cylindrical carbon nanotube may form a cylindrically-shaped coating around the nanotube. Such properties may be advantageous, for example, when preservation of directionally dependent properties of a material (e.g., nanostructures) is desired and known coating techniques may produce undesired irregularities and morphological changes (e.g., due to agglomeration of nanostructures) that may adversely affect the anisotropy of the material. In some cases, conformal coatings may be formed on materials having a high aspect ratio (e.g., nanostructures). Additionally, the conformal coating may form a stable structure and may not delaminate from the surface of the nanostructures.

In some cases, conformal coatings described herein may be formed on nanostructure assemblies having high density, wherein individual nanostructures are coated conformally over a substantial portion of the surface area of the nanostructures. In some cases, the conformal coating may have a substantially uniform thickness. A material having a “substantially uniform” thickness may refer to a material having a thickness which deviates less than 200%, less than 100%, less than 50%, less than 10%, less than 5%, or, in some cases, less than 1%, from an average thickness of the material, over a majority of the surface area of the nanostructure assembly. In some cases, the conformal coating may be substantially free of defects and/or voids, and may uniformly encapsulate the underlying material, or portion thereof.

The presence of a conformal coating attached to nanostructures can provide many advantageous properties to articles described herein. As used herein, the terms “attached” or “adhered” refer to attachment or adhesion via covalent bonds, non-covalent bonds (e.g., ionic bonds, van der Waals forces, etc.), and the like. In some cases, the conformal coating may enhance the mechanical stability and/or strength of the underlying material. In some cases, the conformal coating may be used to impart a desired property onto the underlying nanostructures in a manner that does not substantially disturb the alignment, spacing, morphology, or other desired characteristic of the nanostructures. For example, the article may exhibit a different property (e.g., thermal and/or electrical conductivity, heat transfer, hydrophobicity, hydrophilicity, etc.) when compared to an essentially identical article lacking the conformal coating, under essentially identical conditions. In an illustrative embodiment, a plurality of essentially to non-conductive nanostructures may be provided, and, upon formation of a conformal coating comprising a conducting polymer, the nanostructures may exhibit enhanced electrical conductivity. In some cases, conductive nanostructures can be conformally coated with an essentially non-conductive material (e.g., an insulating polymer).

Formation of a conformal coating on a plurality of nanostructures may also effectively alter the surface energy of the nanostructures. In some cases, the conformal coating may increase the surface energy, relative to the uncoated, underlying material. In some cases, the conformal coating may decrease the surface energy, relative to the uncoated, underlying material. For example, the conformal coating may render the surface of the material, or portion thereof, hydrophobic or hydrophilic, as determined by contact angle measurements.

The conformal coating may be formed using various methods, including chemical vapor deposition, and from any suitable material. In some embodiments, the material may be polymeric. The conformal coating may be conductive, non-conductive, semiconductive, or the like. In some embodiments, the conformal coating may comprise a conducting polymer, including polyarylenes, polyarylene vinylenes, polyarylene ethynylenes, and the like. Examples of such polymers include polythiophenes, polypyrroles, polyacetylenes, polyphenylenes, substituted derivatives thereof, and copolymers thereof. In some embodiments, the polymer may include polypyrrole (PPY), poly(3,4-ethylenedioxythiophene) (PEDOT), poly(thiophene-3-acetic acid) (PTAA), or copolymers thereof. In some embodiments, the polymer comprises an insulating polymer (i.e., non-conductive), such as polyesters, polyethylenes (e.g., polytetrafluoroethylene (PTFE)), polyacrylates, polypropylenes, epoxy, polyamides, polyimides, polybenzoxazoles, poly(amino acids), and the like. For example, the polymer may be TEFLON®, poly(glycidyl methacrylate) (PGMA), poly(maleic anhydride-alt-styrene) (p(MA-alt-St)), poly [maleic anhydride-co-dimethyl acrylamide-co-di(ethylene glycol) divinyl ether] (poly(MaDmDe)), poly(furfuryl methacrylate) (PFMA), poly(vinyl pyrrolidone) (PVP), poly(para-xylylene) or its derivatives, poly(dimethylaminomethyl styrene) (PDMAMS)), poly(propargyl methacrylate) (PPMA), poly(methacrylic acid-co-ethyl acrylate) (PMAA-co-EA), poly(perfluoroalkyl ethyl methacrylate), poly(perfluorodecyl acrylate) (PPFA), poly(trivinyltrimethoxycyclotrisiloxane), poly(furfuryl methacrylate), poly(cyclohexyl methacryateco-ethylene glycol dimethacrylate), poly(cyclohexyl methacrylate) to (PCHMA), poly(pentafluorophenyl methacrylate) (PPFM), poly(pentafluorophenyl methacrylate co-ethylene glycol diacrylate), poly(methacrylic acid-co-ethylene glycol dimethacrylate), poly(methyl methacrylate) (PMMA), or poly(3,4-ethylenedioxythiophene. Those of ordinary skill in the art would be able to identify additional insulating polymers suitable for use in the context of the invention.

In some embodiments, at least one dimension of the polymer (e.g., thickness) may change in response to a stimulus. Examples of stimuli to which a dimension of a polymer may be responsive include, but are not limited to, electromagnetic radiation (e.g., wavelength, intensity, etc.), temperature, moisture level, pH, or concentration of a chemical species. Any suitable stimulus-responsive polymer can be used in association with the systems and methods described herein. In some embodiments, the polymer may comprise poly(methacrylic acid-co-ethyl acrylate) (PMAA-co-EA), the dimensions of which can change in response to changes in pH. As another example, the polymer may be a hydrogel such as poly(2-hydroxyethyl methacrylate) (pHEMA), poly(2-hydroxyethyl methacrylate-co-ethylene glycol diacrylate), poly(methacrylic acid-co-ethylene glycol dimethacrylate), poly(para-xylylene) (parylene), or poly(trivinyltrimethylcyclotrisiloxane) (PV₃D₃), which can experience a change in one or more dimensions upon exposure to varying levels of moisture. In some embodiments, the polymer may be a thermosensitive polymer such as, for example, poly(N-isopropylacrylamide) (NIPAAM). In some embodiments, the polymer may have a first dimension (e.g., thickness) upon exposure to a first stimulus condition (e.g., a first wavelength of electromagnetic radiation, a first pH, a first temperature, etc.). In some cases, the polymer may have a second dimension (e.g., thickness) that is different from the first dimension when it is exposed to a second stimulus condition that is different from the first stimulus condition (e.g., a second, different wavelength of electromagnetic radiation, pH, temperature, etc.).

As noted above, some embodiments described herein may provide conformally coated nanostructures having high aspect ratio, wherein the conformal coating may substantially encapsulate the nanostructures. The nanostructures may be nanotubes (e.g., single-walled nanotubes, multi-walled nanotubes), nanowires, nanofibers, and the like. In some embodiments, at least some of the nanostructures have a length of at least 10 microns, at least 50 microns, at least 100 microns, at least 500 microns, at least 1000 microns, or, in some cases, greater. In some embodiments, at least some of the nanostructures have a diameter less than 75 nm, less than 50 nm, less than 25 nm, less than 20 nm, less than 15 nm, less than 10 nm, less than 7 nm, less than 5 nm, or, in some cases, less than 2 nm.

In some cases, the nanostructures within the articles may be closely spaced, wherein the conformal coating may be formed along the length (e.g., over a substantial portion of the surface area) of the nanostructures as well as on areas between adjacent, closely spaced nanostructures, i.e., exposed areas of an underlying substrate. For example, the nanostructures may have a density of at least 10⁸/cm², at least 10⁹/cm², or greater. In some embodiments, the average distance between adjacent nanostructures may be less than about 80 nm, less than about 60 nm, less than about 40 nm, less than about 30 nm, less than about 20 nm, less than about 10 nm, less than about 5 nm, or smaller. In some cases, the nanostructure materials or the nanocomposites may comprise a high volume fraction of nanostructures. For example, the volume fraction of the nanostructures within the materials may be at least about 0.01%, at least about 0.05%, at least about 0.1%, at least about 0.5%, at least about 1%, at least about 5%, at least about 10%, at least about 20%, at least about 40%, at least about 60%, at least about 70%, at least about 75%, or, in some cases, at least about 78%.

Such materials may be useful in producing various articles (e.g., two-phase articles, three-phase articles, four-phase articles, or greater) having tunable properties, including electrical properties, mechanical properties, and the like. The plurality of nanostructures may, in some cases, be arranged on the surface of a substrate, such as a substantially flat surface or a substantially nonplanar surface. For example, the substrate may be a fiber, weave, cloth, tow, woven tow, etc.). The substrate, nanostructures, conformal coating material, and any additional components may be selected in combination to suit a particular application.

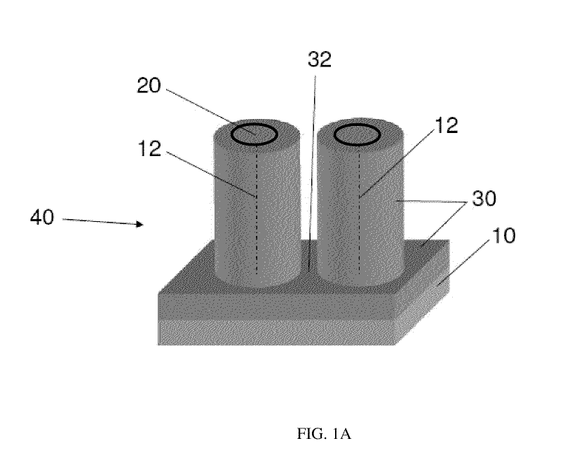

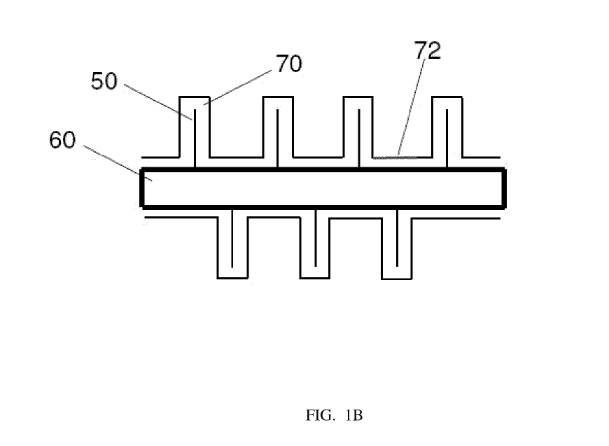

In some embodiments, a two-phase article is provided, wherein a nanostructure assembly (e.g., “first phase”) is conformally coated by a material (e.g., “second phase”). FIG. 1A includes a schematic illustration of two-phase article 40. A plurality of nanostructures 20 is provided such that the long axes of the nanostructures, indicated by dashed lines 12, are substantially aligned relative to each other. Each nanostructure is positioned relative to an adjacent nanostructure at a distance so as to together define an average distance between adjacent nanostructures. Conformal coating 30 may be formed on the nanostructures 20 as well as on portions of substrate 10. As noted above, an advantage of some embodiments described herein is the ability to form conformal coatings on nanostructures having high density and/or aspect ratio. In cases where the density of nanostructures on a surface is such that at least some of the substrate surface is not covered with nanostructures, the conformal coating may substantially coat the exposed portions of the substrate surface as well. As shown in FIG. 1A, conformal coating can be formed along a substantial length (e.g., entire length) of nanostructures 20 and on portions 32 of the substrate, positioned in areas between closely packed, high aspect ratio nanostructures.

In some cases, the substrate may be substantially non-planar, with the plurality of nanostructures arranged radially around and/or uniformly over a substantial majority of the non-planar surface. FIG. 1B shows an illustrative embodiment in which nanostructures 50 are arranged on a cylindrical fiber 60, and conformal coating 70 has been formed on the nanostructures as well as exposed portions 72 of substrate 60.

In some embodiments, the two-phase article may include an assembly of carbon nanotubes arranged on a substrate, and a conformal coating formed on the carbon nanotubes, wherein the conformal polymer coating comprises a conducting polymer such as PEDOT.

Additional components may also be incorporated into articles of the invention, as described more fully below. For example, at least one support material may be associated with the plurality of nanostructures, i.e., as a conformal or non-conformal coating. In some embodiments, a “three-phase article” is demonstrated. The three-phase article may include a nanostructure assembly (e.g., “first phase”), conformally coated by a second material (e.g., “second phase”), as well as an additional support material (e.g., “third phase”). In some embodiments, the support material may comprise a polymer, such as a thermoset polymer or a thermoplastic polymer (e.g., epoxy, PTFE).

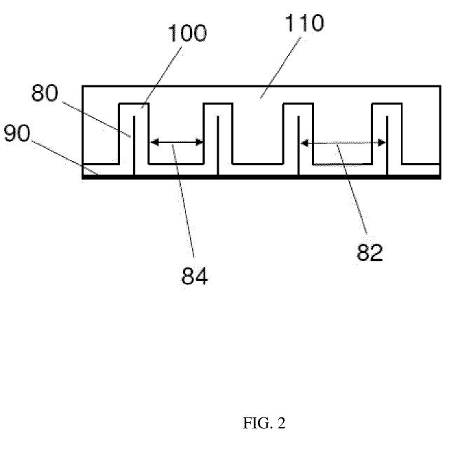

FIG. 2 illustrates a three-phase article according to one embodiment of the invention. The three-phase article can include a plurality of nanostructures 80 grown on substrate 90 and having a conformal coating 100. A support material 110 may be applied to the coated nanostructures to form a three-phase article. In some embodiments, the support material extends substantially along the entire length of the nanostructures. The support material may also fill essentially all of the void space between the nanostructures. In some embodiments, the support material may not completely cover the nanostructures. For instance, the support material may be applied such that the nanostructures extend above the surface of the support material.

In other embodiments, the support material may be formed on portions of the nanostructures. For example, the support material may be formed along a substantial length at least some nanostructures. In some embodiments, the support material may be formed partially along the length of the nanostructures, for example, leaving portions of the nanostructures closest to the substrate surface substantially free of support material. In some cases, the support material may be formed as a conformal coating on the nanostructures.

In some embodiments, the three-phase article may include an assembly of carbon nanotubes arranged on a substrate, a conformal coating comprises a conducting polymer such as PEDOT formed on the carbon nanotubes, and a support material comprising a thermoset or thermoplastic polymer (e.g., epoxy) formed on the conformal coating.

In one set of embodiments, three-phase articles described herein may be useful as high surface area electrochemical devices (e.g., capacitors). For example, as shown in FIG. 2, an assembly of electrically conductive nanostructures 80 (e.g., nanotubes) may be arranged on the surface of substrate 90, which may be optionally electrically conductive, to provide an electrically active component. A first coating 100 comprising a dielectric material (e.g., a insulating polymer) may be conformally positioned on the electrically conductive nanostructures 80. A second coating 110 comprising an electrically conductive material may be arranged, conformally or non-conformally, in contact with first coating 100, to form another electrically active component, such that nanostructures 80 and second coating 110 may be in electrical communication with one another through first coating 100. Such an arrangement may provide electrochemical devices with active components having high surface area and enhanced electrical properties.

Articles described herein may be readily tailored to suit a particular application. For example, the aspect ratio, length, diameter, spacing, and type of nanostructures may be varied, as well as the type of conformal coating material(s). Articles having additional components or phases may also be produced using methods described herein. For example, articles including any number of phases may be fabricated in any arrangement.

Some embodiments (e.g., arrangements such as those described in association to with FIGS. 1A-1B and FIG. 2) may allow for relatively efficient operation in electrodes. For example, the use of thin nanostructures (e.g., nanotubes) can result in a large surface area to volume ratio. Not wishing to be bound by any theory, the relatively low amount of bulk volume can reduce the amount of recombination of electrons and holes as they are generated in the electrode, which may lead to a relative increase in the amount of electrons that are transported away from the electrode. Such operation can increase the amount of work done by the electrode, relative to electrodes with larger amounts of bulk material.

Some embodiments may find particular use as part of a capacitor (e.g., an ultracapacitor). Not wishing to be bound by any particular theory, the capacitance of a capacitor can be proportional to the electrode surface area and inversely proportional to the distance between the electrodes. In some embodiments, conductive layers (e.g., a plurality of nanotubes on a conductive substrate, an electrically conductive layer over a pluarlity of nanotubes, and the like) can have relatively high surface area. In addition, in some embodiments, the distance between conductive layers can be controlled in some cases (e.g., by depositing a relatively thin layer of non-conducting polymer over a conductive entity such as a plurality of conductive nanostructures) such that it is relatively small (e.g., less than about 80 nm, less than about 60 nm, less than about 40 nm, less than about 30 nm, less than about 20 nm, less than about 10 nm, less than about 5 nm, less than about 1 nm, or smaller). Such embodiments can produce capacitors with relatively high capacitance.

Methods for producing the articles and materials described herein are also provided. The methods may include providing a plurality of nanostructures, as described herein, and forming a conformal coating on the nanostructures. The nanostructures may be arranged such that the long axes of the nanostructures are substantially aligned relative to each other. In some cases, the nanostructures may be fabricated by uniformly growing the nanostructures on the surface of a substrate, such that the long axes are aligned and non-parallel to the substrate surface (e.g., substantially perpendicular to the substrate surface). In some cases, the long axes of the nanostructures are oriented in a substantially perpendicular direction with respect to the surface of a substrate, forming a nanostructure “forest.” In some embodiments, at least some of the nanostructures may have a length (e.g., a dimension along the long axis of the nanostructure) of at least 10 microns.

The nanostructures may be catalytically formed on the surface of a substrate. For example, a nanostructure precursor material (e.g., a hydrocarbon gas such as C₂H₄, H₂, hydrogen, argon, nitrogen, combinations thereof, and the like) may be contacted with a catalyst material (e.g., nanoparticles of Fe), for example, positioned on the surface of a substrate. Examples of suitable nanostructure fabrication techniques are discussed in more detail in International Patent Application Serial No. PCT/US2007/011914, filed May 18, 2007, entitled “Continuous Process for the Production of Nanostructures Including Nanotubes,” published as WO 2007/136755 on Nov. 29, 2007, and International Patent Application Serial No. PCT/US2007/011913, filed May 18, 2007, entitled “Nanostructure-Reinforced Composite Articles,” published as WO/2008/054541, on May 8, 2008, which are incorporated herein by reference in its entirety.

In some embodiments, the alignment of nanostructures in the nanostructure “forest” may be substantially maintained, even upon subsequent processing (e.g., application of a force to the forest, conformal coating of the forest, transfer of the forest to other surfaces, and/or combining the forests with secondary materials such as polymers, metals, ceramics, piezoelectric materials, piezomagnetic materials, carbon, and/or fluids, among other materials).

As noted above, conformal coatings may be formed on a plurality of nanostructures, as well as portions of the substrate on which the nanostructures are arranged, i.e., the exposed portions of the substrate. For example, the conformal coating may be formed along a substantial length of nanostructures having high aspect ratio and on portions of an underlying substrate positioned between adjacent nanostructures, as shown in FIGS. 1A and 1B. The conformal coating may be formed using various methods, including chemical vapor deposition (CVD). That is, the nanostructures may be exposed to one or more conformal coating precursors (e.g., monomeric species) in vapor phase, such that a conformal coating is formed on the surface of the nanostructures.

The use of CVD may be advantageous in that substantially uniform coatings may be formed on a wide range of substrate materials, i.e., formation of conformal coating use in CVD may be substrate-independent. Additionally, CVD may be performed at relatively low temperatures (e.g., less than 500° C., less than 300° C., less than 100° C., less than 50° C., less than 30° C.). In some embodiments, dry chemical vapor deposition methods may be used. Some embodiments involve use of a chemical vapor deposition method at room temperature and/or without use of a hot filament to activate polymerization of monomeric species.

In some embodiments, oxidizing chemical vapor deposition (oCVD) methods may be used, wherein both an oxidant and a monomeric material are provided in the vapor phase for deposition. For example, a solid oxidant may be sublimed in vapor phase prior to contacting the nanostructures. In an illustrative embodiment, an iron chloride oxidizing agent is heated to 350° C. for sublimation process, and the substrate to be coated is maintained at 70° C., with a coating duration of about 15 minutes and a flow rate of monomer (e.g., EDOT monomer) of 5 sccm.

In some embodiments, initiated chemical vapor deposition (iCVD) methods may be used, wherein an initiator is included in addition to one or more monomers. In some embodiments, relatively low energies can be employed when using an initiator, which may be useful when depositing polymer on, for example, relatively delicate substrates (e.g., very thin metal foils, tissue paper, etc.). In some such embodiments, the initiator can be thermally decomposed. For example, in some cases, an array of resistively heated filaments within a vacuum chamber can be heated to drive the pyrolysis of the initiator while allowing the substrate to remain cool enough to promote the adsorption of the species required for film growth. Examples of suitable initiators can include, but are not limited to, perfluorooctane sulfonyl fluoride, triethylamine, tert-butyl peroxide, 2,2′-azobis (2-methylpropane), and benzophenone.

In some embodiments, the formation of a conformal coating does not substantially change the average distance between adjacent nanostructures or the alignment of the nanostructures. For example, prior to the formation of the conformal coating, the nanostructures may have a first average distance between adjacent nanostructures, and, after formation of the conformal coating, the nanostructures may have a second average distance between adjacent nanostructures, wherein the first and second average distances are substantially the same. As used herein, average distances which are “substantially the same” are differ from one another by less than 10%, less than 5%, less than 1%, or, in some cases, less than 0.5%. In some cases, the average distance may refer to the distance between the centers of adjacent nanostructures or coated nanostructures (e.g., distance 82 in FIG. 2). In some cases, the average distance may refer to the intertube distance between adjacent coated nanostructures, i.e., the distance between outer surfaces or edges of two adjacent coated nanostructures (e.g., to distance 84 in FIG. 2).

The formation of a conformal coating may, in some embodiments, change the average distance between adjacent nanostructures. In some embodiments, formation of a conformal coating can reduce the average spacing between nanostructures by at least about 10%, at least about 25%, at least about 50%, at least about 75%, at least about 90%, between about 10% and about 99%, between about 10% and about 90%, between about 10% and about 75%, between about 10% and about 50%, between about 10% and about 25%, between about 25% and about 99%, between about 50% and about 99%, or between about 75% and about 99%. The ability to change the average distance between adjacent nanostructures can be useful in producing a plurality of nanostructures with a relatively close, and in some cases substantially uniform, average distance between adjacent nanostructures. For example, in some cases, formation of a conformal coating can produce an average spacing between a plurality of nanostructures of less than about 1 micron, less than about 500 nm, less than about 100 nm, less than about 80 nm, less than about 60 nm, less than about 40 nm, less than about 30 nm, less than about 20 nm, less than about 10 nm, or less than about 5 nm The ability to produce uniformly closely spaced nanostructures can be useful, for example, in embodiments where consistent and close spacing of the nanostructures, prior to formation of a coating, is difficult to achieve. In some embodiments, the thickness of the conformal coating may be selected (e.g., by varying a coating formation parameter such as temperature, pressure, type of coating precursor, or concentration of coating precursor) to achieve a predetermined average spacing between adjacent coated nano structures.

The ability to control the average distance between adjacent nanostructures (e.g., via deposition of a conformal polymer coating) can allow one to fabricate, for example, filters that are able to separate out a specific range of particle sizes (e.g., nanoparticle sizes) upon passing a fluid including a wide range of particle sizes through the nanostructures. For example, in some embodiments, a flow of a fluid containing first and second populations of particles can be established through the plurality of nanostructures (e.g., conformally coated nanostructures). The first population can include particles with maximum cross-sectional dimensions greater than the average distance between adjacent nanostructures, and the second population can include particles with maximum cross-sectional dimensions smaller than the average distance between adjacent nanostructures. After establishing a flow of a fluid containing the first to and second populations toward the nanostructures, the first population may be at least partially separated from the second population. In some embodiments, at least a portion of the first population can be retained by the nanostructures while at least a portion of the second population is passed through the nanostructures. In some embodiments, the first and second populations can be substantially completely separated.

The embodiments described herein can be used to at least partially separate a variety of types of particles. For example, in some cases, the particles can comprise quantum dots, biological molecules, and the like. As a specific example, some embodiments can be useful as relatively inexpensive water filters that can be used to separate harmful bacteria such as E. coli.

As used herein, the “maximum cross-sectional dimension” refers to the largest distance between two opposed boundaries of an individual structure (e.g., a particle) that may be measured. The “average maximum cross-sectional dimension” of a plurality of structures refers to the number average.

In some embodiments (e.g., where stimulus-responsive polymers are used), the average distance between adjacent nanostructures may change with a variation in a stimulus condition (e.g., electromagnetic radiation, temperature, pH, chemical species concentration, etc.). In some cases, the polymer may have a first dimension (e.g., thickness) upon exposure to a first stimulus condition, and the polymer may have a second dimension (e.g., thickness) that can be different from the first dimension upon exposure to a second stimulus condition that is different from the first stimulus condition. The change in the dimension of the polymer may produce a change in the average distance between adjacent nanostructures. As a specific example, in some embodiments, a plurality of nanostructures may have a first average distance between adjacent nanostructures at a first pH and a second average distance between adjacent nanostructures (that can be different from the first average distance) at a second pH that is different from the first pH. In some instances, a plurality of nanostructures may have a first average distance between adjacent nanostructures at a first temperature and a second average distance between adjacent nanostructures (that can be different from the first average distance) at a second temperature that is different from the first temperature. As another example, a plurality of nanostructures may have a first average distance between adjacent nanostructures upon exposure to a first wavelength of electromagnetic radiation and a second average distance between adjacent nanostructures (that can be different to from the first average distance) upon exposure to a second wavelength of electromagnetic radiation that is different from the first wavelength of electromagnetic radiation. In some embodiments, variations in moisture level, concentration of a chemical species, or any other suitable stimulus can be used to produce a similar effect.

Controlling the average spacing between adjacent nanostructures using a stimulus condition can be useful, for example, in creating a tunable filter. In such embodiments, the sizes of the particles that are separated can be dependent upon the stimulus condition to which the nanostructures are exposed. For example, in some embodiments, a flow of a fluid containing first, second, and third populations of particles can be established through the plurality of nanostructures (e.g., conformally coated nanostructures). The first population can include particles with relatively large maximum cross-sectional dimensions, the second population can include particles with maximum cross-sectional dimensions smaller than the particles in the first population, and the third population can include particles with maximum cross-sectional dimensions smaller than the particles in the first and second populations. Upon exposing the nanostructures to a first stimulus condition (e.g., a first temperature, a first pH, a first wavelength of electromagnetic radiation, etc.) a first average distance between adjacent nanostructures can be established. The first average distance between adjacent nanostructures can be smaller than the maximum cross-sectional dimensions of the particles in the first population, but larger than the maximum cross-sectional dimensions of the particles in the second and third populations. Upon flowing a fluid mixture of the first, second, and third populations through the nanostructures, the first population can be at least partially separated from the second and third populations. In some cases, the first population may be at least partially retained by the nanostructures while the second and third populations are at least partially passed through the nanostructures.

Upon exposure to a second stimulus condition (e.g., a second temperature, a second pH, a second wavelength of electromagnetic radiation, etc.) a second average distance between adjacent nanostructures (e.g., different from the first average distance between adjacent nanostructures) can be established. The second average distance between adjacent nanostructures can be smaller than the maximum cross-sectional dimensions of the particles in the second population, and larger than the maximum cross-sectional dimensions of the particles in the third population. Upon flowing a fluid to containing the second and third populations through the nanostructures, the second population may be at least partially separated from the third population. In some cases, the second population can be at least partially retained by the nanostructures while the third population can be at least partially passed through the nanostructures. In some embodiments, substantially complete separation of the second and third populations can be achieved. Such a process can be repeated for any number of stimulus conditions and can be used to separate (partially or substantially completely) any number of populations of particles.

Some embodiments of the invention may further comprise treating the nanostructures, for example, to change the density of the nanostructures. In some cases, the densification (e.g., uniaxial or biaxial densification) is performed prior to forming the conformal coating on the nanostructures. The nanostructure assembly be treated via chemical, mechanical, or other methods, to change (e.g., increase, decrease) the average distance between adjacent nanostructures. For example, the nanostructures treated by mechanical means to increase the density of nanostructures, and may subsequently be conformally coated as described above. Methods for changing the density of nanostructures are described in U.S. Provisional Patent Application Ser. No. 61/114,967, filed Nov. 14, 2008, entitled “Controlled-Orientation Films and Nanocomposites Including Nanotubes or Other Nanostructures,” which is incorporated herein by reference.

In some instances, a force with a component normal to the long axes of the nanostructures may be applied to the plurality of nanostructures reduce their spacing, i.e., to reduce the average distance between adjacent nanostructures. In some embodiments, a second force may be applied to the nanostructures. The second force may include a second component that is normal to the long axes of the nanostructures and orthogonal to the first component of the first force. The method may also include additional densification steps, if needed. Application of such force(s) may produce a material comprising a high volume fraction or mass density of nanostructures.

The force described herein may be applied using any method known in the art. In some embodiments, a mechanical tool is used to apply the force to the plurality of nanostructures. For example, an operator may apply a flat surface of a tool (e.g., a plastic plunger) against the side of a plurality of nanostructures, and compress the nanostructures by hand. In some embodiments, the force may be applied using compression springs. For example, the plurality of nanostructures may be situated in an enclosed or semi-enclosed containment structure with one or more compression springs situated between the side of the plurality of nanostructures and an adjacent wall of the containment structure. Forces may be applied using other elements including, but not limited to, weights, machine screws, and/or pneumatic devices, among others. For example, in one set of embodiments, a plurality of nanostructures is arranged between two plates. A device (e.g., a machine screw, a spring, etc.) may be used to apply pressure against the sides of the nanostructures via the plates. In the case of a machine screw, for example, the nanostructures may be compressed between the plates upon rotating the screw. In still other embodiments, a liquid may be applied to the plurality of nanostructures and dried; upon drying, capillary forces may pull the nanostructures together, resulting in a reduction of the average distance between nanostructures. Other methods of applying forces to the plurality of nanostructures can be envisioned by one of ordinary skill in the art.

The application of a first and/or second force may reduce the average distance between adjacent nanostructures by varying amounts. In some cases, the average distance between adjacent nanostructures is reduced by at least about 25%. In some instances, the average distance between adjacent nanostructures is reduced by at least about 50%, at least about 70%, at least about 80%, at least about 90%, at least about 95%, at least about 99%, or more.

As noted above, the methods described herein may be used to produce materials with high volume fractions of nanostructures. As used herein, the volume fraction of nanostructures within a material (e.g., a plurality of nanostructures, a nanocomposite, etc.) is calculated by dividing the sum of the volumes defined by the nanostructures by the total volume defined by the material. It should be noted that the volume defined by a nanostructure may contain some void space. For example, in the case of a hollow nanotube, the volume defined by the nanotube would include the interior void space within the tube.

Additional components may be incorporated within articles described herein. In some cases, at least one support material may be applied to the nanostructures to provide mechanical, chemical, or an otherwise stabilizing support for the plurality of nanostructures. In some cases, the support material may be a monomer, a polymer, a fiber, a ceramic, or a metal, and may be further processed to support the nanostructures. In some embodiments, a support material precursor may be added to the nanostructures and may be treated to form a support material associated with the nanostructures. For example, a mixture of monomeric species may be added to the nanostructures, and subsequent polymerization of the monomeric species may produce a polymer matrix comprising the nanostructures disposed therein. In another example, a polymeric species may be added to the nanostructures, and subsequent hardening of the polymeric species may produce a polymer matrix comprising the nanostructures disposed therein. Examples of suitable support materials are described more fully below.

The support material precursor may be added to the nanostructures using various methods. In some embodiments, the support material precursor may be transported between the nanostructures via capillary forces. For example, the nanostructure assembly (e.g., nanotube “forest”) may contact the surface of a pool or solution of the support material precursor, such that the support material precursor infuses into the nanostructure assembly, filling in the spaces between individual nanostructures while maintaining alignment of and spacing between the nanostructures. In some cases, the nanostructure assembly may be submerged within the support material precursor. Capillary-induced wetting may be performed at various rates, depending on the characteristics of the nanostructures assembly (e.g., volume fraction, surface conditions) and the type of support material (e.g., viscosity). In some embodiments, articles comprising nanostructures of lengths exceeding 1 mm and volume fractions greater than 20% may be wetted with support material, or precursors thereof. In an illustrative embodiment, the plurality of nanocomposites is transported by a z-stage and submerged in a pool of epoxy precursor. The epoxy precursor is transported between nanostructures via capillary action, and the nanostructures are removed from the epoxy pool. In other embodiments, the support material precursor may be transported between the nanostructures by pressure driven flow, molding, or any other known technique.

In other embodiments, the support material precursor may be solidified or hardened using any suitable method. The epoxy may be cured, for example, by allowing the precursor material to set, or optionally by applying heat. In some embodiments, hardening may comprise the polymerization of the support material precursor.

In some cases, the support material precursor may be applied to a plurality of nanostructures that form a self-supporting structure, or the support material precursor may be applied to a plurality of nanostructures that are attached to a substrate. In addition, nanostructures may be solidified while attached to or apart from a substrate and/or any other support material.

In some cases, the nanostructures are dispersed substantially uniformly within the hardened support material. For example, the nanostructures may be dispersed substantially uniformly within at least 10% of the hardened support material, or, in some cases, at least 20%, 30%, 40%, 50%, 60%, 70%, 80%, 90%, 95%, or 100% of the hardened support material. As used herein, “dispersed uniformly within at least X % of the hardened support material” refers to the substantially uniform arrangement of nanostructures within at least X % of the volume of the hardened support material. The ability to arrange nanostructures essentially uniformly throughout structures comprising plurality of fibers allows for the enhanced mechanical strength of the overall structure.

The nanostructures may be further treated to improve the properties of the nanostructure material at any step of the fabrication process. In some cases, the nanostructures may be annealed.

In some cases, the method may comprise the act of removing the nanostructures from a substrate. In some cases, the nanostructures may be covalently bonded to the substrate, and the removal step comprises breaking at least some of the covalent bonds. The act of removing may comprise transferring the nanostructures directly from the surface of a first substrate (e.g., a growth substrate) to a surface of a second substrate (e.g., a receiving substrate). Removal of the nanostructures may comprise application of a mechanical tool, mechanical or ultrasonic vibration, a chemical reagent, heat, or other sources of external energy, to the nanostructures and/or the surface of the substrate. For example, a scraping (“doctor”) or peeling blade, and/or other means such as an electric field may be used to initiate and continue delamination of the nanostructures from the substrate. In some cases, the nanostructures may be removed by application of compressed gas, for example. In some cases, the nanostructures may be removed (e.g., detached) and collected in bulk, without attaching the nanostructures to a receiving substrate, and the nanostructures may remain in their original or “as-grown” orientation and conformation (e.g., in an aligned “forest”) following removal from the substrate.

In one set of embodiments, the attachment between the nanostructures and a substrate may be altered by exposing the nanostructures and/or substrate to a chemical (e.g., a gas). Exposing the nanostructures and/or substrate to the chemical may, in some cases, substantially reduce the level of attachment or adhesion between the to nanostructures and the substrate. Examples of chemicals that are useful in reducing the level of attachment between the nanostructures and the substrate include, but are not limited to, hydrogen, oxygen, and air, among others. In some cases, elevated temperatures (e.g., temperatures greater than about 100° C.) may be used to expedite the detachment of nanostructures from the substrate. For example, nanostructures (e.g., carbon nanotubes) may be grown on a substrate and subsequently exposed to hydrogen gas while they remain in the processing chamber. Exposing the nanostructures to hydrogen may, in some cases, result in the delamination of the nanostructures from the substrate. In some embodiments, exposing the nanostructures to hydrogen may not result in the complete delamination of the plurality of nanostructures, but may, for example, result in the breaking of a large enough fraction of the bonds such that the force required to remove the plurality of nanostructures is reduced by at least about 50%, at least about 70%, at least about 90%, at least about 95%, at least about 99%, or more.

Removal of the nanostructures may also comprise application of a mechanical tool, mechanical or ultrasonic vibration, a chemical reagent, heat, or other sources of external energy, to the nanostructures and/or the surface of the substrate. In some cases, the nanostructures may be removed by application of compressed gas, for example. In some cases, the nanostructures may be removed (e.g., detached) and collected in bulk, without attaching the nanostructures to a receiving substrate, and the nanostructures may remain in their original or “as-grown” orientation and conformation (e.g., in an aligned “forest”) following removal from the substrate.

An external force may be used to initiate and continue delamination of the layer from the first substrate, and to direct the layer toward the second substrate. For example a scraping (“doctor”) or peeling blade, and/or other means such as an electric field may be used to initiate and continue delamination. In some cases, the layer may be delaminated and/or handled as a film, tape, or web. Alternatively, the film may be suspended, handled, and optionally mechanically (e.g., rolled, compacted, densified), thermally or chemically (e.g., purified, annealed) treated in a continuous fashion prior to being transferred to the second substrate.

Methods described herein may be used to control the dimensions and other properties of a plurality of nanostructures. As described herein, the nanostructures may be coated conformally with a material that imparts a particular property (e.g., electrical property) onto the nanostructures. In some embodiments, a plurality of nanostructures to may be provided such that the long axes of the nanostructures are substantially aligned, and the plurality has a thickness defined by the long axes of the nanostructures (e.g., by the average length of the long axes of the nanostructures). The average length of the long axes of the plurality of nanostructures may be controlled, for example, by adjusting parameters (e.g., type of reactant used, time over which the nanostructures are grown, etc.) of the growth process. In some cases, the average length of the long axes of the plurality of nanostructures may be controlled by a post processing step such as polishing (e.g., chemical-mechanical polishing), chemical treatment, or some other step. In some embodiments, the average spacing between adjacent nanostructures may be controlled by the application of a force with a component normal to the long axes of the nanostructures.

In some embodiments, the conformal coating, as well as the length, thickness, and density of the nanostructures are together selected to form an article having a desired level of absorption of electromagnetic radiation, conductivity, resistance, modulus, or some other property. Articles described herein may also comprise tunable multi-functional properties. For example,

As noted above, the presence of nanostructures within articles described herein may impart desirable properties such as improved mechanical strength and/or toughness, thermal and/or electrical conductivity, heat transfer, and surface characteristics (e.g., hydrophobicity, hydrophilicity). For example, in some cases a composite material may exhibit a higher mechanical strength and/or toughness when compared to an essentially identical material lacking the set of substantially-aligned nanostructures, under essentially identical conditions, while the alignment or morphology of nanostructures remain essentially unaffected. In some embodiments, the nanostructures may be arranged to enhance the intralaminar interactions of components within a material or substrate, to enhance the interlaminar interactions of two substrates or plies within a composite structure, or to mechanically strengthen or otherwise enhance the binding between the two substrates, among other functions. In some cases, the thermal, electrical conductivity, and/or other properties (e.g., electromagnetic properties, specific heat, etc.) of articles described herein may be selected to be directionally dependent (e.g., anisotropic).

As used herein, the term “nanostructure” refers to elongated chemical structures having a diameter on the order of nanometers and a length on the order of microns to to millimeters or more, resulting in an aspect ratio greater than 10, 100, 1000, 10,000, or greater. The term “long axis” is used to refer to the imaginary line drawn parallel to the longest length of the nanostructure and intersecting the geometric center of the nanostructure. In some cases, the nanostructures may have an average diameter of less than about 1 um, less than about 500 nm, less than about 250 nm, less than about 100 nm, less than about 75 nm, less than about 50 nm, less than about 25 nm, less than about 10 nm, or, in some cases, less than about 1 nm. In some instances, the nanostructure has a cylindrical or pseudo-cylindrical shape. The nanostructure may be, for example, a nanotube (e.g., a carbon nanotube), a nanowire, or a nanofiber, among others. In some embodiments, the nanostructures used in the systems and methods described herein may be grown on a substrate. In other embodiments, the nanostructures may be provided separately from the substrate, either attached to another substrate, or as a self-supporting structure detached from any substrate.

In some embodiments, the articles and methods described herein comprise carbon-based nanostructures. Examples of carbon-based nanostructures include carbon nanotubes, carbon nanowires, carbon nanofibers, and the like. It should be understood that the nanostructures described herein may include atoms other than carbon.

Materials described herein may also be formed over a large surface area. In some embodiments, the originally provided plurality of nanostructures extends a distance at least 10 times greater than the average distance between adjacent nanostructures in each of two orthogonal directions, each direction perpendicular to the long axes. In some cases, the plurality of nanostructures extends, in two orthogonal directions each perpendicular to the long axes, a distance at least 100 times greater, at least 1000 times greater, at least 10,000 times greater, at least 100,000 times greater, at least 1,000,000 times greater, or longer than the average distance between adjacent nanostructures.

In some embodiments, the plurality of nanostructures may be provided as a self-supporting material. In other cases, the nanostructures may be attached to a substrate (e.g., a growth substrate). In some embodiments, the long axes of the nanostructures are substantially aligned and non-parallel to the substrate surface, having a thickness defined by the long axes of the nanostructures.

The nanostructures may comprise any desirable aspect ratio. In some cases, a plurality of nanostructures may be provided such that the plurality extends, in at least one dimension (e.g., in one dimension, in two orthogonal dimensions, etc.) substantially perpendicular to the long axes, a distance at least about 1.5 times greater, at least about 2 times greater, at least about 5 times greater, at least about 10 times greater, at least about 25 times greater, at least about 100 times greater, or more than a dimension substantially parallel to the long axes of the nanostructures. As a specific example, the plurality of nanostructures may constitute a thin-film such that the long axes of the nanostructures are substantially perpendicular to the largest surface of the film. A plurality of nanostructures may be provided, in some instances, such that the plurality extends, in at least one dimension substantially parallel to the long axes, a distance at least about 1.5 times greater, at least about 2 times greater, at least about 5 times greater, at least about 10 times greater, at least about 25 times greater, at least about 100 times greater, or more than a dimension substantially perpendicular to the long axes of the nanostructures.

In some cases, at least 10%, at least about 20%, at least about 30%, at least about 40%, at least about 50%, at least about 60%, at least about 70%, or more of the nanostructures extend substantially through thickness of the plurality of nanostructures.

As used herein, the term “nanotube” is given its ordinary meaning in the art and refers to a substantially cylindrical molecule or nanostructure comprising a fused network of primarily six-membered aromatic rings. In some cases, nanotubes may resemble a sheet of graphite formed into a seamless cylindrical structure. It should be understood that the nanotube may also comprise rings or lattice structures other than six-membered rings. Typically, at least one end of the nanotube may be capped, i.e., with a curved or nonplanar aromatic group. Nanotubes may have a diameter of the order of nanometers and a length on the order of millimeters, or, on the order of tenths of microns, resulting in an aspect ratio greater than 100, 1000, 10,000, or greater. In some cases, the nanotube is a carbon nanotube. The term “carbon nanotube” refers to nanotubes comprising primarily carbon atoms and includes single-walled nanotubes (SWNTs), double-walled CNTs (DWNTs), multi-walled nanotubes (MWNTs) (e.g., concentric carbon nanotubes), inorganic derivatives thereof, and the like. In some embodiments, the carbon nanotube is a single-walled carbon nanotube. In some cases, the carbon nanotube is a multi-walled carbon nanotube (e.g., a double-walled carbon nanotube). In some cases, the nanotube may have a diameter less than 1 μm, less than 100 nm, 50 nm, less than 25 nm, less than 10 nm, or, in some cases, less than 1 nm. In one set of embodiments the nanotubes have an average diameter of 50 nm or less, and are arranged in composite articles as described herein. The inorganic materials include semiconductor nanowires such as silicon (Si) nanowires, indium-gallium-arsenide (InGaAs) nanowires, and nanotubes comprising boron nitride (BN), silicon nitride (Si₃N₄), silicon carbide (SiC), dichalcogenides such as (WS₂), oxides such as titanium dioxide (TiO₂) and molybdenum trioxide (MoO₃), and boron-carbon-nitrogen compositions such as BC₂N₂ and BC₄N.

Substrates suitable for use in the invention include prepregs, polymer resins, dry weaves and tows, inorganic materials such as carbon (e.g., graphite), metals, alloys, intermetallics, metal oxides, metal nitrides, ceramics, and the like. In some cases, the substrate may be a fiber, tow of fibers, a weave, and the like. The substrate may further comprise a conducting material, such as conductive fibers, weaves, or nanostructures. In some embodiments, the substrates used herein are substantially transparent to electromagnetic radiation. For example, in some cases, the substrate may be substantially transparent to visible light, ultraviolet radiation, or infrared radiation. In other cases, the nanostructures may be provided as a self-supporting structure free of a substrate and/or any other material. In some embodiments, the substrate may comprise alumina, silicon, carbon, a ceramic, or a metal.

In some cases, the substrate may be hollow and/or porous. In some embodiments, the substrate is porous, such as a porous Al₂O₃. As used herein, a “porous” material is defined as a material having a sufficient number of pores or interstices such that the material is easily crossed or permeated by, for example, a fluid or mixture of fluids (e.g., liquids, gases). In some embodiments, the substrate is a fiber comprising Al₂O₃, SiO₂, or carbon. In some embodiments, the substrate may comprise a layer, such as a transition metal oxide (Al₂O₃) layer, formed on surface of an underlying material, such as a metal or ceramic.

In some cases, the substrates as described herein may be prepregs, that is, a polymer material (e.g., thermoset or thermoplastic polymer) containing embedded, aligned, and/or interlaced (e.g., woven or braided) fibers such as carbon fibers. As used herein, the term “prepreg” refers to one or more layers of thermoset or thermoplastic resin containing embedded fibers, for example fibers of carbon, glass, silicon carbide, and the like. In some embodiments, thermoset materials include epoxy, rubber strengthened epoxy, BMI, PMK-15, polyesters, vinylesters, and the like, and preferred to thermoplastic materials include polyamides, polyimides, polyarylene sulfide, polyetherimide, polyesterimides, polyarylenes, polysulfones, polyethersulfones, polyphenylene sulfide, polyetherimide, polypropylene, polyolefins, polyketones, polyetherketones, polyetherketoneketone, polyetheretherketones, polyester, and analogs and mixtures thereof. Typically, the prepreg includes fibers that are aligned and/or interlaced (woven or braided) and the prepregs are arranged such the fibers of many layers are not aligned with fibers of other layers, the arrangement being dictated by directional stiffness requirements of the article to be formed by the method. The fibers generally can not be stretched appreciably longitudinally, thus each layer can not be stretched appreciably in the direction along which its fibers are arranged. Exemplary prepregs include TORLON thermoplastic laminate, PEEK (polyether etherketone, Imperial Chemical Industries, PLC, England), PEKK (polyetherketone ketone, DuPont) thermoplastic, T800H/3900-2 thermoset from Toray (Japan), and AS4/3501-6 thermoset from Hercules (Magna, Utah).

Substrates described herein may be any material capable of supporting catalyst materials and/or nanostructures as described herein. The substrate may be selected to be inert to and/or stable under sets of conditions used in a particular process, such as nanostructure growth conditions, nanostructure removal conditions, and the like. In some embodiments, the substrate may be selected to be conductive. In some cases, the substrate comprises a substantially flat surface. In some cases, the substrate comprises a substantially nonplanar surface. For example, the substrate may comprise a cylindrical surface (e.g., fiber).

As described herein, the invention may comprise use or addition of one or more binding materials or support materials. The binding or support materials may be polymer materials, fibers, metals, or other materials described herein. Polymer materials for use as binding materials and/or support materials, as described herein, may be any material compatible with nanostructures. For example, the polymer material may be selected to uniformly “wet” the nanostructures and/or to bind one or more substrates. In some cases, the polymer material may be selected to have a particular viscosity, such as 50,000 cPs or lower, 10,000 cPs or lower, 5,000 cPs or lower, 1,000 cPs or lower, 500 cPs or lower, 250 cPs or lower, or 100 cPs or lower. In some embodiments, the polymer material may be selected to have a viscosity between 150-250 cPs. In some cases, the polymer material may be a thermoset or thermoplastic. In some cases, the polymer to material may optionally comprise a conducting material, including conductive fibers, weaves, or nanostructures.

Examples of thermosets include Microchem SU-8 (UV curing epoxy, grades from 2000.1 to 2100, and viscosities ranging from 3 cPs to 10,000 cPs), Buehler Epothin (low viscosity, ˜150 cPs, room temperature curing epoxy), West Systems 206+109 Hardener (low viscosity, ˜200 cPs, room temperature curing epoxy), Loctite Hysol 1C (20-min curing conductive epoxy, viscosity 200,000-500,000 cPs), Hexcel RTM6 (resin transfer molding epoxy, viscosity during process ˜10 cPs), Hexcel HexFlow VRM 34 (structural VARTM or vacuum assisted resin transfer molding epoxy, viscosity during process ˜500 cPs). Examples of thermoplastic include polystyrene, or Microchem PMMA (UV curing thermoplastic, grades ranging from 10 cPs to ˜1,000 cPs). In one embodiment, the polymer material may be PMMA, EpoThin, WestSystems EPON, RTM6, VRM34, 977-3, SU8, or Hysol1C.

In some cases, the support material may be a monomeric species and/or a polymer comprising cross-linking groups, such that polymerization and/or cross-linking of the polymers may form a hardened structure comprising the aligned nanostructures. In other embodiments, the support material may be a metal or a metal powder such as a metal nanoparticles having diameter on the order of the diameter of the nanostructures or the spacing between the nanostructures on the substrate. The metal may be softened, sintered, or melted when added to the aligned nanostructures, such that cooling of the metal may form a metal structure comprising the aligned nanostructures. As used herein, an “integrally self-supporting structure” is defined as a non-solid structure having sufficient stability or rigidity to maintain its structural integrity (e.g., shape) without external support along surfaces of the structure. Solid and/or self-supporting structures comprising aligned nanostructures may be useful as substrate or other components for composite materials, as described herein.

Polymers or polymer materials, as used herein, refer to extended molecular structures comprising a backbone (e.g., non-conjugated backbone, conjugated backbone) which optionally contain pendant side groups, where “backbone” refers to the longest continuous bond pathway of the polymer. In one embodiment, at least a portion of the polymer is conjugated or pi-conjugated, i.e. the polymer has at least one portion along which electron density or electronic charge can be conducted, where the electronic charge is referred to as being “delocalized.” Each p-orbital participating in conjugation to can have sufficient overlap with adjacent conjugated p-orbitals. In one embodiment, at least a portion of the backbone is conjugated. In one embodiment, a substantial majority of the backbone is conjugated and the polymer is referred to as a “pi-conjugated polymer” or “conjugated polymer.” Polymers having a conjugated pi-backbone capable of conducting electronic charge may be referred to as “conducting polymers.” In some cases, the conjugated pi-backbone may be defined by a plane of atoms directly participating in the conjugation, wherein the plane arises from a preferred arrangement of the p-orbitals to maximize p-orbital overlap, thus maximizing conjugation and electronic conduction. In some cases, the pi-backbone may preferably have a non-planar or twisted ground state conformation, leading to decreased conjugation and a higher energy conduction band.

The polymer can be a homo-polymer or a co-polymer such as a random co-polymer or a block co-polymer. In one embodiment, the polymer is a block co-polymer. An advantageous feature of block co-polymers is that they may mimic a multi-layer structure, wherein each block may be designed to have different band gap components and, by nature of the chemical structure of a block co-polymer, each band gap component is segregated. As described herein, the band gap and/or selectivity for particular analytes can be achieved by modification or incorporation of different polymer types. The polymer compositions can vary continuously to give a tapered block structure and the polymers can be synthesized by either step growth or chain growth methods.

The following applications and patents are incorporated herein by reference in their entirety for all purposes: International Patent Application Serial No. PCT/US2007/011914, filed May 18, 2007, entitled “Continuous Process for the Production of Nanostructures Including Nanotubes,” published as WO 2007/136755 on Nov. 29, 2007; International Patent Application Serial No. PCT/U.S.07/11913, filed May 18, 2007, entitled “Nanostructure-reinforced Composite Articles and Methods,” published as WO 2008/054541 on May 8, 2008; U.S. patent application Ser. No. 11/386,378, filed Mar. 22, 2006, entitled “Nano-Engineered Material Architectures: Ultra-Tough Hybrid Nanocomposite System”; U.S. patent application Ser. No. 11/895,621, filed Aug. 24, 2007, entitled “Nanostructure-Reinforced Composite Articles,” published as U.S. Patent Application Publication No. 2008/0075954 on Mar. 27, 2008; International Patent Application Serial No. PCT/US2008/009996, filed Aug. 22, 2008, entitled “Nanostructure-reinforced Composite Articles and Methods,” published as WO 2009/029218 on Mar. 5, 2009; U.S. Pat. No. 7,537,825, issued on May 26, 2009, entitled “Nano-Engineered Material Architectures: Ultra-Tough Hybrid Nanocomposite System;” U.S. Provisional Patent Application Ser. No. 61/114,967, filed Nov. 14, 2008, entitled “Controlled-Orientation Films and Nanocomposites Including Nanotubes or Other Nanostructures;” U.S. patent application Ser. No. 12/618,203, filed Nov. 13, 2009, entitled “Controlled-Orientation Films and Nanocomposites Including Nanotubes or Other Nanostructures;” U.S. Provisional Patent Application Ser. No. 61/119,673, filed on Dec. 3, 2008, entitled “Multifunctional Composites Based on Coated Nanostructures;” U.S. Provisional Patent Application 61/230,267, filed Jul. 31, 2009, entitled “Systems and Methods Related to the Formation of Carbon-Based Nanostructures;” and U.S. Provisional Patent Application 61/264,506, filed Nov. 25, 2009, entitled “Systems and Methods for Enhancing Growth of Carbon-Based Nanostructures;” each of which is incorporated herein in its entirety.

The following examples are intended to illustrate certain embodiments of the present invention, but do not exemplify the full scope of the invention.

### EXAMPLES

### Example 1

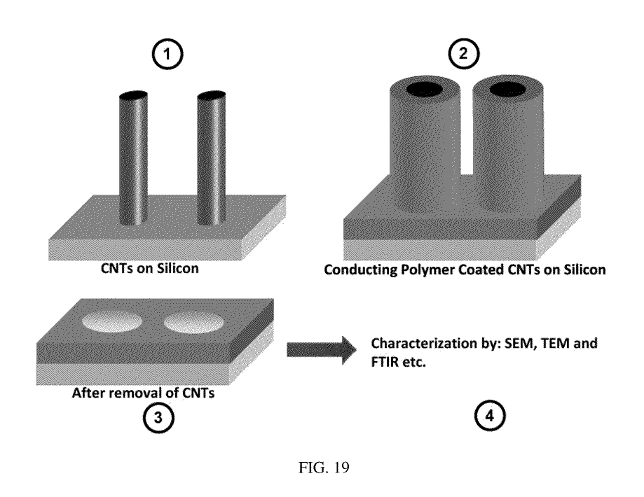

This example demonstrates the fabrication of a two-phase composite of CNTs and conducting polymers. The fabrication process is shown schematically in FIG. 19, wherein (1) carbon nanotubes are grown on a silicon substrate, (2) a conformal polymer coating is formed on the carbon nanotubes and silicon substrate, (3) the coated carbon nanotubes are removed from the substrate, and (3) characterization using SEM, TEM, FTIR, and other methods, is performed.

Multi-walled carbon nanotubes (MWNTs) were grown by thermal chemical vapor deposition (CVD) method on silicon wafers using a thin catalyst layer of Fe/Al₂O₃ (1/10 nm) deposited by electron beam evaporation. CNT growth was performed in a quartz tube furnace (22 mm ID) at atmospheric pressure. Ethylene was employed as the source of carbon for obtaining the CNTs. The typical growth temperature was 750° C., and the growth rate was 2 microns/second. Typically, CNT forests were grown on 1 cm² silicon wafers, which resulted in well aligned CNTs having densities of about 10⁹-10¹⁰ CNTs/cm². Following the growth of CNTs, a H₂/He gas mixture was flushed at 750° C. for 5 min to achieve easier delamination of CNTs arrays from Si substrate.

Deposition of PEDOT on CNT arrays was accomplished using the oxidative chemical vapor deposition process (oCVD). Briefly, the CNT arrays were held face down in a vacuum chamber, facing the oxidizing agent. Mere heating of the oxidizing agent allowed for its sublimation onto the substrate. Further reaction of this incoming oxidizing agent with the EDOT monomer (supplied through the vapor phase) resulted in the formation of PEDOT film on the CNT array substrate. All PEDOT deposition experiments were performed at a substrate temperature of 70° C. The samples were gently rinsed in isopropanol following PEDOT deposition to remove any excess oxidizing agent present on the samples.

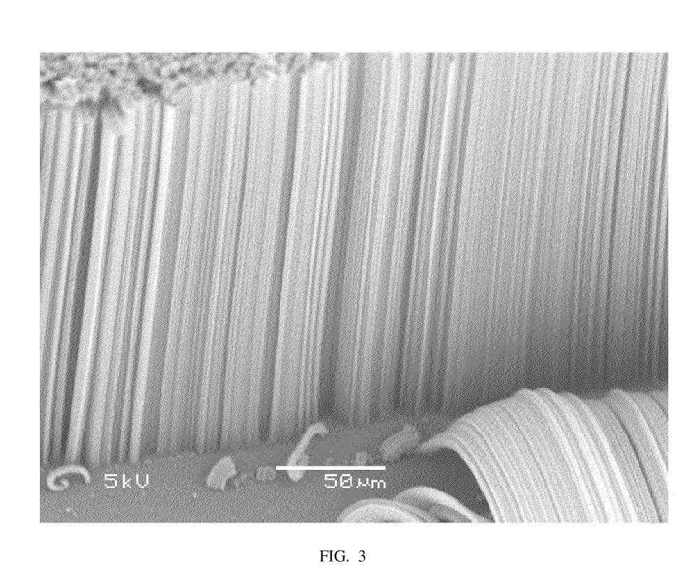

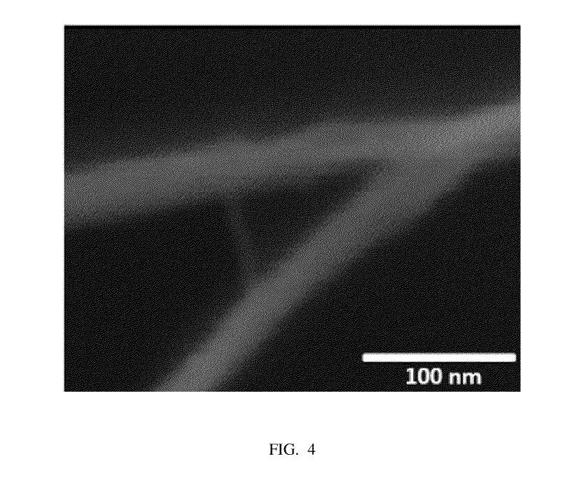

A scanning electron cross-sectional micrograph of PEDOT coated CNT arrays is presented in FIG. 3. As observed in FIG. 3, the orientation and the shape of the CNT array was not disturbed by the oCVD PEDOT coating process. In order to confirm that each individual CNT was coated with PEDOT, these CNTs were removed from the substrate, dispersed in isopropanol, and high resolution microscopy was performed. A high magnification image of the dispersed CNTs showed that the diameter of individual CNTs was 30 nm after PEDOT deposition (FIG. 4) indicating that there was a 10 nm PEDOT coating around each nanotube.

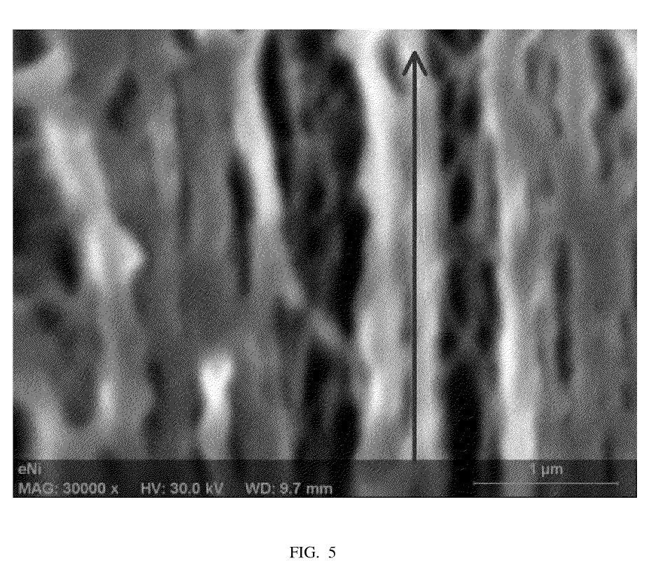

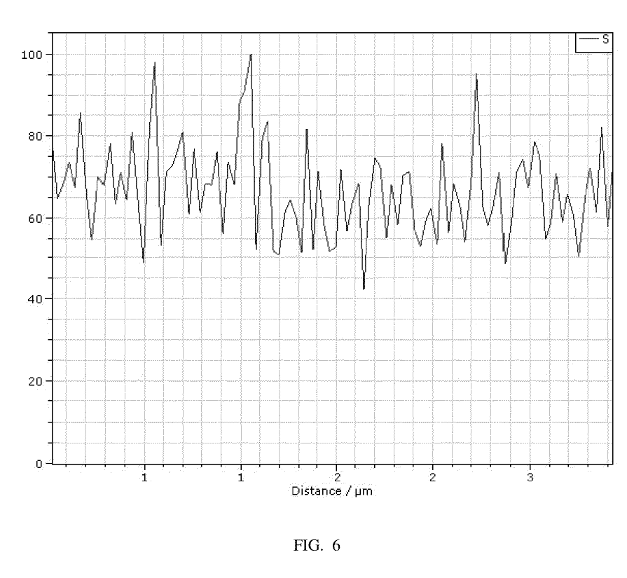

To confirm further the presence of PEDOT around the CNTs, energy dispersive analysis (EDS) was performed along the length of the PEDOT coated CNT array. Micrographs of PEDOT coated CNT arrays along with a line profile of sulfur are presented in FIGS. 5 and 6, respectively. The analysis showed the presence of sulfur along the length of the array. Further, the concentration of sulfur was found to be uniform along the length of the array (FIG. 6). It is worthwhile to note here that sulfur comes only from the PEDOT component of the composite.

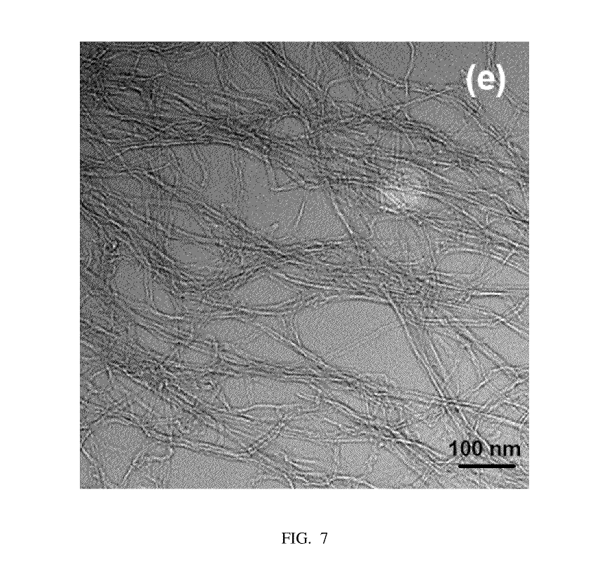

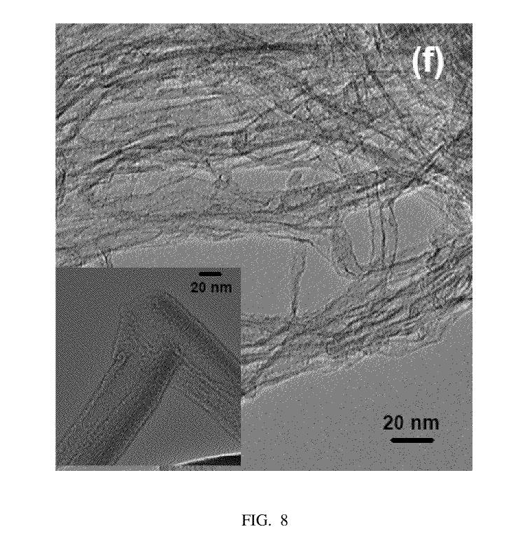

Transmission electron microscopy before deposition (FIG. 7) and after deposition (FIG. 8) also showed that the CNTs are coated with PEDOT. The thick coating at the edge of each tube is indicative of the presence of PEDOT around CNTs (FIG. 8). A high magnification TEM image shown in the inset to FIG. 8 shows the thickness contrast between the edge and the center of a CNT.

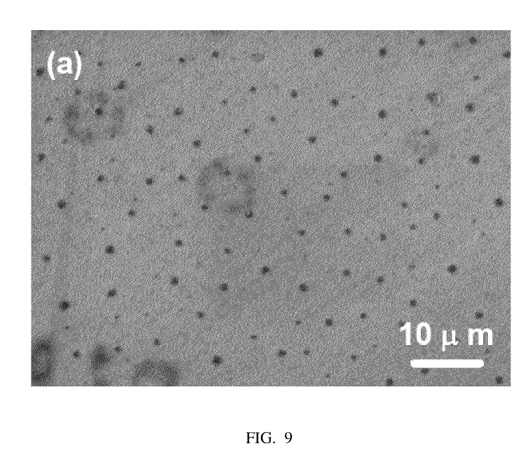

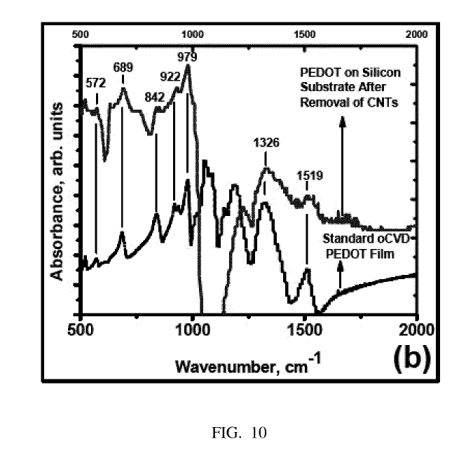

Additional evidence that PEDOT conformally coated the CNTs came from the observed presence of PEDOT on the silicon substrate supporting the CNT arrays, which was observed only on the regions of the substrate devoid of any carbon nanotubes (In this example, 1% volume fraction CNTs had an inter-tube distance of 80 nm). A to micrograph showing the presence of PEDOT on the silicon substrate after removal of CNTs is shown in FIG. 9. The dot pattern observed is indicative of the presence of PEDOT on the substrate. FT-IR analysis of the silicon substrate confirmed the presence of PEDOT on the substrate. A comparison of an FTIR spectrum of a PEDOT coating on top of the silicon substrate (supporting the carbon nanotubes) with an FTIR spectrum of a standard PEDOT film deposited on pristine silicon wafers is presented in FIG. 10. As observed in FIG. 10, the spectrum of PEDOT present on the silicon substrate supporting the carbon nanotubes displayed the modes typically observed in PEDOT films. The vibration modes of the C—S bond at 689 cm⁻¹, 842 cm⁻¹ and 979 cm⁻¹ and the ethylenedioxy ring deformation mode at 922 cm⁻¹ are observed in the spectrum shown in FIG. 10. The absence of a C—H mode at 890 cm⁻¹ indicated that the polymerization occurred at the 2 and 5 positions.

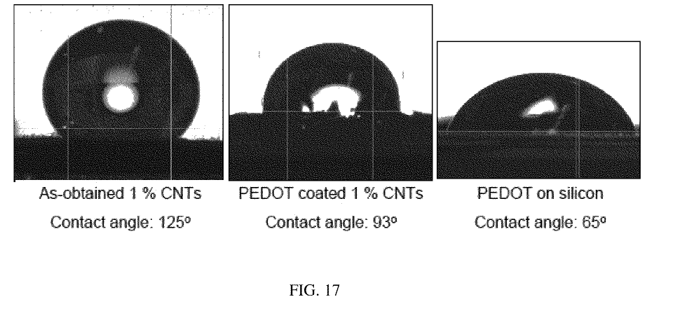

FIG. 17 shows images of contact angle measurements of water droplets on various surfaces including (i) un-coated carbon nanotubes, (ii) PEDOT-coated carbon nanotubes, and (iii) PEDOT. The resulting contact angle measurements demonstrated that the hydrophobicity of PEDOT-coated 1% volume fraction CNTs was intermediate) (93°) in comparison to 1% volume fraction CNTs)(125°) and PEDOT coated silicon)(65°) (FIG. 17). The wetting behavior of the coated carbon nanotubes is also expected to be directional dependant.

### Example 2

This example demonstrates the fabrication of three-phase composites.

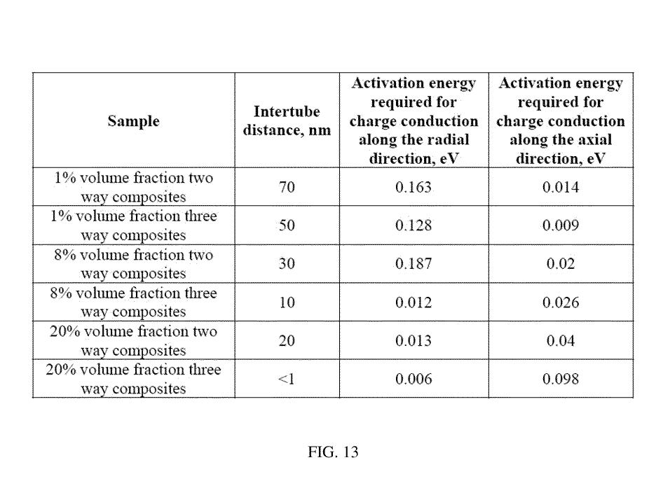

Following the deposition of PEDOT on the CNT arrays, the two-phase composites were lowered into a pool of epoxy and cured to obtain three-phase composites (comprising CNTS, PEDOT, and epoxy). CNT forests were biaxially compressed and then coated with PEDOT. The PEDOT coated forests were then lowered into a pool of uncured epoxy. An aero grade epoxy, RTM 6 (epoxy has a viscosity of 33 cP at 90° C.), was employed for this purpose. The epoxy infused into the CNT arrays through capillary driven wetting. Following the infusion of the epoxy, the entire composites were cured at 200° C. in air. As-obtained CNT arrays are referred to as 1% volume fraction, the densified CNT arrays are referred to as 5%, 8%, and 20% volume fraction. The intertube distance between conformally coated nanostructures corresponding to the volume fractions is presented in FIG. 13. As used in this Example, the “intertube distance” refers to the distance between the outer surfaces (e.g., outer surface of the conformal coating) of two, adjacent conformally coated nanostructures.

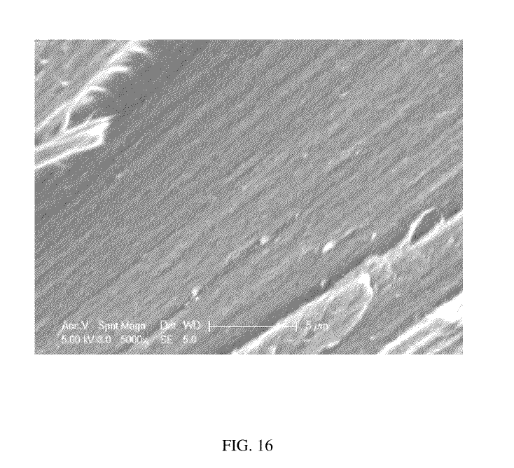

FIG. 16 shows scanning-electron micrograph cross-sectional images of three-phase composites comprising carbon nanotubes conformally coated with PEDOT, with an additional epoxy layer formed on and between the coated carbon nanotubes. The three-phase composite was cut and the cross-section was observed under SEM. As shown in FIG. 16, individual nanostructures can be observed after fabrication of the three-phase composite. The diameter of the individual conformally coated nanotubes was measured to be about 50 nm, indicating that the carbon nanotubes did not agglomerate, i.e., were not “bundled up,” during the composite fabrication process. Rather, the observed diameter of an individual nanostructure indicated the presence of an individual carbon nanotube having a diameter of about 10 nm, a PEDOT coating formed on the individual carbon nanotube with a thickness of about 10 nm, giving an overall outer diameter of the coated nanotube of about 30 nm, and an epoxy component.

### Example 3

This example demonstrates the electrical characterization of PEDOT coated CNT three-phase composites using two-point probe electrical measurements.

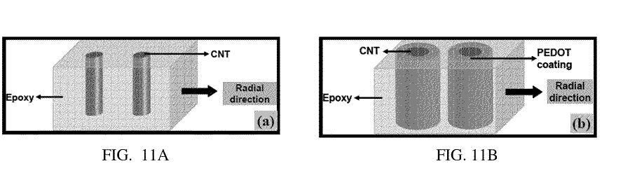

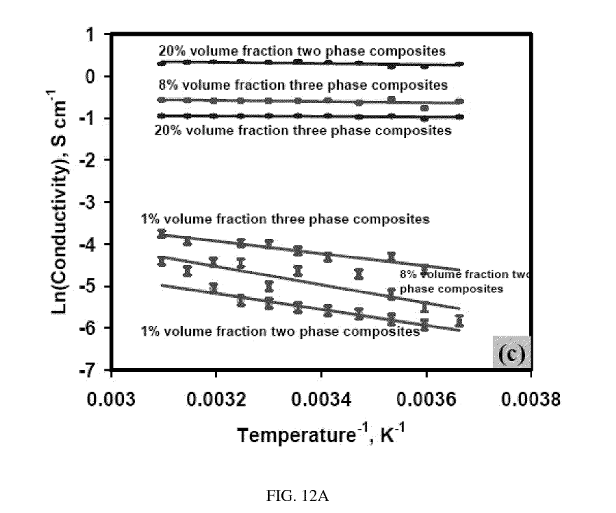

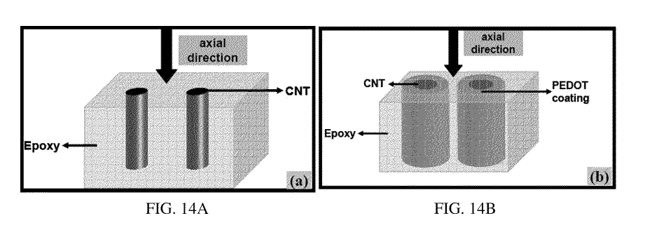

In order to understand the electrical behavior of the composites, the change in the resistance of the composites with temperature was studied. The resistance measurements were performed using two-point probe measurements without the use of any additional metal contact pads. The obtained resistances were then converted into conductivity. FIG. 11 shows schematic representations of (a) a two-phase composite and (b) a three-phase composite, with the radial direction indicated by arrows. FIG. 14 shows schematic representations of (a) a two-phase composite and (b) a three-phase composite, with the axial direction indicated by arrows.

For a semi-infinite sample, the resistivity (ρ) can be obtained from the resistance (R) using the relationship ρ=RA/L. Here, L is the distance between the probes and A is the cross-sectional area. The conductivity could then be obtained from resistivity using the relationship σ=1/ρ. The data along the radial (transverse to CNT long axis) direction (FIG. 11) of the composite samples showed that the variation of resistivity with temperature followed the VRH model and that the resistivity was proportional to T^{-1/3}. According to the VRH variable range hopping model, conductivity occurs by hopping of to charge carriers and the resistivity (ρ) follows the following relationship with temperature: ρ=ρ₀e{(T₀/T)̂[1/(n+1)]}. Here, T₀ is the characteristic temperature and n is the dimensionality of the conduction. The variation of resistivity with temperature is observed to be fit best when n=3. This result indicated that the conductivity along the radial direction in the composites was two-dimensional.

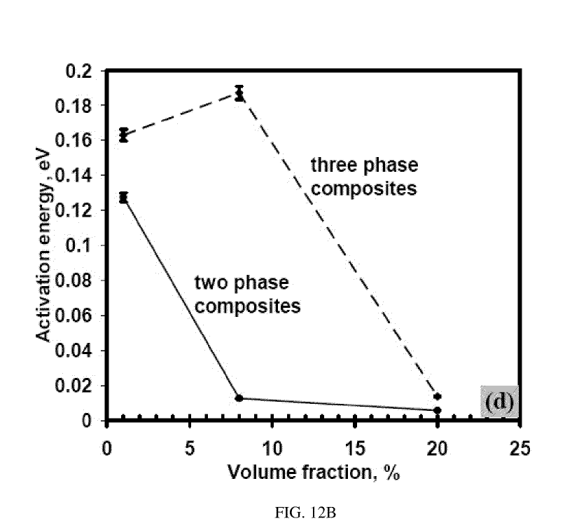

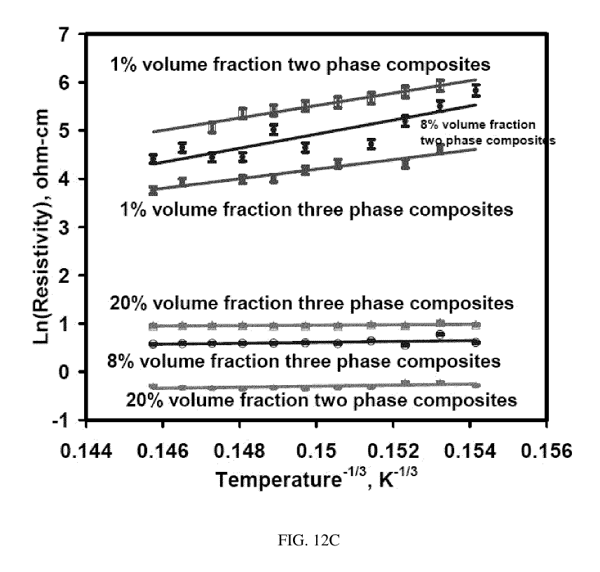

An Arrhenius plot of the variation of conductivity with inverse of temperature in the radial direction (FIG. 12A) showed that the activation energy required for the creation of mobile charge carriers was inversely proportional to the volume fraction (i.e., proportional to the intertube distance). This activation energy (FIG. 12B) was also lower in three-phase composites as compared to two-phase composites. Further, the decrease in activation energy between the two-phase and three-phase composites was higher in lower volume fraction composites as compared to higher volume fraction composites. As the volume fraction of the composites increased (i.e., the intertube distance decreased), the effect of the introduction of the conducting polymers on the activation energy was expected to be lower than that observed due to the reduction in intertube distance. The variation of resistivity with temperature (FIG. 12C) in the radial direction indicates that the conductivity is three-dimensional in these composites.

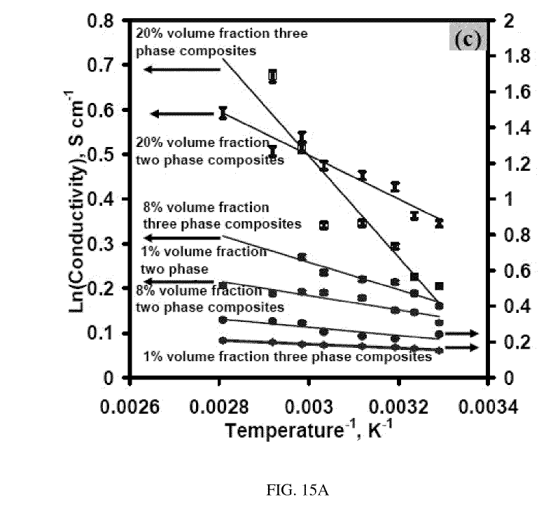

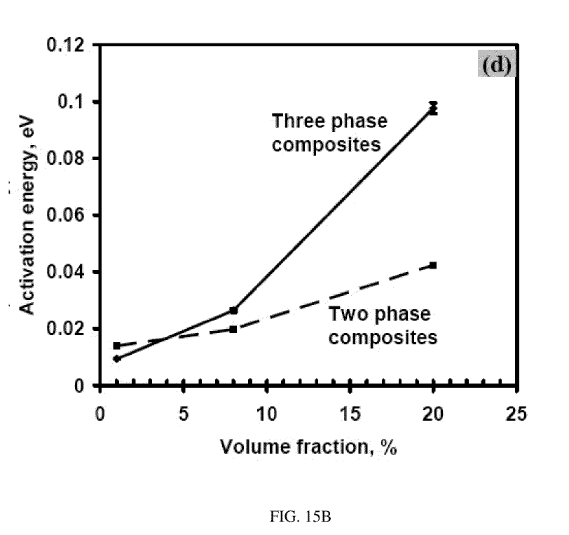

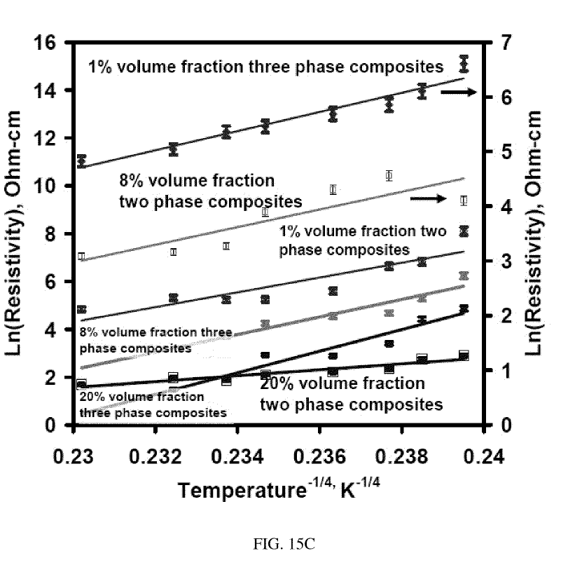

In contrast, in the axial direction, the conduction was primarily along the length of the CNTs. (FIG. 15A) Hence, the activation energy was not expected to vary considerably with variation in intertube distance. As shown in FIG. 15B, the activation energy was lower in two-phase composites as compared to three-phase composites. The introduction of conducting polymer was also not expected to vary the activation energy as the contribution to conductivity was dominated by the CNTs themselves. FIG. 15C shows a plot of resistivity of various composites as a function of temperature in the axial direction. The activation energies in the axial direction were found to considerably lower than those observed in the radial direction (FIG. 12C). The activation energies were found to be very low for all samples (0.009 to 0.098 eV) (FIG. 13).

This analysis indicated that the composites exhibited directional dependant behavior and that the alignment of the CNT forests was not disturbed by the conducting polymer deposition process. The wetting behavior of the CNT forests was also found to be directional dependant.

### Example 4

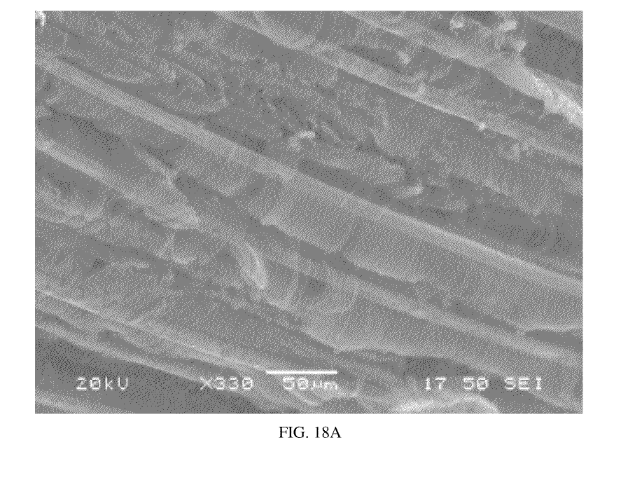

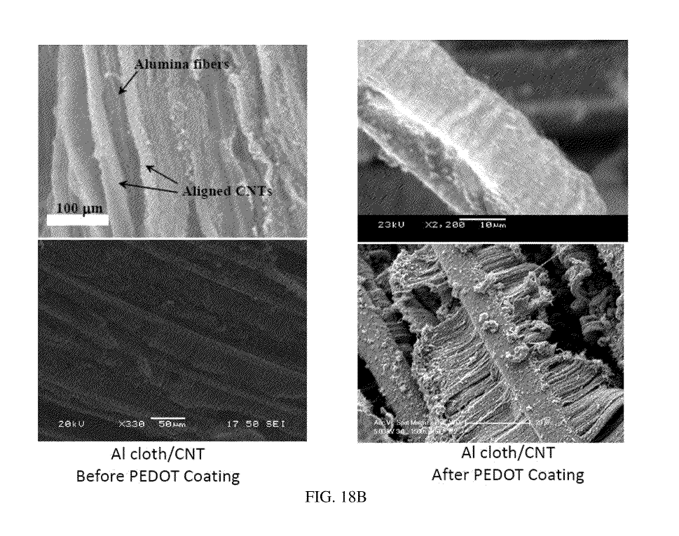

This example describes the fabrication of three-phase composite including an Al cloth (e.g., fibers), carbon nanotubes, and a PEDOT conformal coating. Using the methods described herein, a three-phase composite was fabricated by growing carbon nanotubes on an Al cloth and then conformally coating the carbon nanotubes and Al cloth with PEDOT. FIG. 18A shows an SEM image of an Al cloth with carbon nanotubes without a conformal polymer coating. FIG. 18B shows SEM images of an Al cloth with carbon nanotubes prior to conformally coating with PEDOT (left images) and after to conformally coating with PEDOT (right images).

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present invention.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that to are conjunctively present in some cases and disjunctively present in other cases. Other elements may optionally be present other than the elements specifically identified by the “and/or” clause, whether related or unrelated to those elements specifically identified unless clearly indicated to the contrary. Thus, as a non-limiting example, a reference to “A and/or B,” when used in conjunction with open-ended language such as “comprising” can refer, in one embodiment, to A without B (optionally including elements other than B); in another embodiment, to B without A (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, to A, and at least one, optionally including more than one, B (and optionally including other elements); etc.

In the claims, as well as in the specification above, all transitional phrases such as “comprising,” “including,” “carrying,” “having,” “containing,” “involving,” “holding,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

What is claimed is:

1. An article, comprising:
a plurality of nanostructures at least some of which have a length of at least 10 microns, the long axes of the nanostructures being substantially aligned relative to each other; and
a conformal polymer coating attached to the nanostructures, wherein the nanostructures have a morphology substantially similar to a morphology of essentially identical nanostructures lacking the polymer coating, under essentially identical conditions.

2. An article, comprising:
a plurality of nanostructures at least some of which have a diameter less than 20 nm, the long axes of the nanostructures being substantially aligned relative to each other; and
a conformal polymer coating attached to the nanostructures, wherein the nanostructures have a morphology substantially similar to a morphology of essentially identical nanostructures lacking the polymer coating, under essentially identical conditions.

3. An article, comprising:
a plurality of nanostructures, wherein the long axes of the nanostructures are substantially aligned relative to each other and the nanostructures have a density of at least 10⁸/cm²; and
a conformal polymer coating attached to the nanostructures, wherein the nanostructures have a morphology substantially similar to a morphology of essentially identical nanostructures lacking the polymer coating, under essentially identical conditions.

4. An article as in claim 1, wherein the conformal polymer coating comprises a conducting polymer.

5. An article as in claim 4, wherein the conducting polymer comprises a polythiophene, a polypyrrole, a polyacetylene, a polyphenylene, or a copolymer thereof.

6. An article as in claim 4, wherein the conducting polymer comprises polypyrrole, poly(3,4-ethylenedioxythiophene) (PEDOT), poly(thiophene-3-acetic acid) (PTAA), or copolymers thereof.

7. An article as in claim 1, wherein the conformal polymer coating comprises an insulating polymer.

8. An article as in claim 7, wherein the insulating polymer comprises at least one of TEFLON®, poly(glycidyl methacrylate), poly(maleic anhydride-alt-styrene), poly[maleic anhydride-co-dimethyl acrylamide-co-di(ethylene glycol) divinyl ether], poly(furfuryl methacrylate), poly(vinyl pyrrolidone), poly(para-xylylene), poly(dimethylaminomethyl styrene), poly(propargyl methacrylate), poly(methacrylic acid-co-ethyl acrylate), poly(perfluoroalkyl ethyl methacrylate), poly(perfluorodecyl acrylate), poly(trivinyltrimethoxycyclotrisiloxane), poly(furfuryl methacrylate), poly(cyclohexyl methacryateco-ethylene glycol dimethacrylate), poly(pentafluorophenyl methacrylate), poly(pentafluorophenyl methacrylate co-ethylene glycol diacrylate), poly(methacrylic acid-co-ethylene glycol dimethacrylate), poly(methyl methacrylate), and poly(3,4-ethylenedioxythiophene).

9. An article as in claim 1, wherein the conformal polymer comprises a stimulus-responsive polymer.

10. An article as in claim 9, wherein the stimulus-responsive polymer comprises a hydrogel.

11. An article as in claim 10, wherein the hydrogel comprises at least one of poly(2-hydroxyethyl methacrylate), poly(2-hydroxyethyl methacrylate-co-ethylene glycol diacrylate), poly(methacrylic acid-co-ethylene glycol dimethacrylate), poly(para-xylylene), and poly(trivinyltrimethylcyclotrisiloxane).

12. An article as in claim 9, wherein the stimulus-responsive polymer is responsive to changes in pH.

13. An article as in claim 9, wherein the stimulus-responsive polymer is responsive to changes in temperature.

14. An article as in claim 9, wherein the stimulus-responsive polymer is responsive to changes in wavelength of electromagnetic radiation to which the polymer is exposed.

15. An article as in claim 9, wherein the stimulus-responsive polymer is responsive to changes in the concentration of a chemical species.

16. An article as in claim 1, wherein
the polymer has a first dimension upon exposure to a first stimulus condition, and
the polymer has a second dimension that is different from the first dimension upon exposure to a second stimulus condition that is different from the first stimulus condition.

17. An article as in claim 1, wherein
the conformally coated nanostructures have a first average distance between adjacent nanostructures upon exposure to a first stimulus condition, and
the conformally coated nanostructures have a second average distance between adjacent nanostructures that is different from the first average distance upon exposure to a second stimulus condition that is different from the first stimulus condition.

18. An article as in claim 1, further comprising at least one support material associated with the plurality of nano structures.

19. An article as in claim 18, wherein the support material comprises a monomer, a polymer, a fiber, or a metal.

20. An article as in claim 1, wherein the plurality of nanostructures is arranged on a substrate.

21. An article as in claim 20, wherein the substrate comprises a substantially flat surface.

22. An article as in claim 20, wherein the substrate comprises a substantially nonplanar surface.

23. An article as in claim 20, wherein the substrate comprises alumina, silicon, carbon, a ceramic, or a metal.

24. An article as in claim 20, wherein the substrate is a fiber, tow, or weave.

25. An article as in claim 1, wherein the nanostructures comprise nanotubes.

26. An article as in claim 1, wherein the nanostructures comprise nanofibers.

27. An article as in claim 1, wherein the nanostructures comprise nanowires.

28. An article as in claim 1, wherein the nanostructures comprise carbon-based nanostructures.

29. An article as in claim 28, wherein the carbon-based nanostructures comprise carbon nanotubes.

30. An article as in claim 1, wherein the volume fraction of the nanostructures within the article is at least about 0.01%.

31-41. (canceled)

42. An article as in claim 1, wherein the nanostructures have an average diameter of 75 nm or less.

43-45. (canceled)

46. An article as in claim 1, wherein the plurality of nanostructures extends a distance at least 10 times greater than the average distance between adjacent nanostructures in each of two orthogonal directions each perpendicular to the long axes.

47-48. (canceled)

49. An article as in claim 1, wherein the average distance between the nanostructures is less than about 80 nm.

50-55. (canceled)

56. An article as in claim 1, wherein the article is part of a capacitor.

57. An article as in claim 1, wherein the article is part of a sensor.

58. An article as in claim 1, wherein the article is part of a filter.

59. A method of producing a material, comprising:
providing a plurality of nanostructures at least some of which have a length of at least 10 microns, the long axes of the nanostructures being substantially aligned relative to each other; and
forming, on the plurality of nanostructures, a conformal coating comprising a polymeric material.

60. A method as in claim 59, wherein the act of providing comprises:
growing the plurality of nanostructures on a surface of a substrate, wherein the long axes of the nanostructures are substantially aligned and non-parallel to the substrate surface, to form an assembly of nanostructures having a thickness defined by the long axes of the nanostructures.

61-64. (canceled)

65. A method as in claim 60, wherein the substrate is substantially transparent to visible light and/or infrared radiation.

66. A method as in claim 59, wherein the act of forming comprises chemical vapor deposition (CVD).

67. A method as in claim 66, wherein the act of forming comprises dry chemical vapor deposition.

68. A method as in claim 66, wherein the act of forming comprises oxidizing chemical vapor deposition (oCVD).

69. A method as in claim 66, wherein the act of forming comprises initiated chemical vapor deposition (iCVD).

70. A method as in claim 59, wherein, prior to the act of forming, each nanostructure is positioned relative to an adjacent nanostructure at a distance so as to together define a first average distance between adjacent nanostructures, and, after the act of forming, each nanostructure is positioned relative to an adjacent nanostructure at a distance so as to together define a second average distance between adjacent nanostructures,
wherein the first and second average distances are substantially the same.

71. A method as in claim 59, wherein, prior to the act of forming, each nanostructure is positioned relative to an adjacent nanostructure at a distance so as to together define a first average distance between adjacent nanostructures, and, after the act of forming, each nanostructure is positioned relative to an adjacent nanostructure at a distance so as to together define a second average distance between adjacent nanostructures,
wherein the first and second average distances are substantially different.

72. A method as in claim 59, wherein the plurality of nanostructures has an average distance between adjacent nanostructures, and the method further comprises:
establishing a flow of a fluid containing a first population of particles and a second population of particles, wherein:
the first population includes particles with maximum cross-sectional dimensions greater than the average distance between adjacent nanostructures, and
the second population includes particles with maximum cross-sectional dimensions smaller than the average distance between adjacent nano structures; and
at least partially separating the first population of particles from the second population of particles by flowing the fluid through the nanostructures.

73. A method as in claim 59, wherein the method further comprises:
exposing the plurality of nanostructures to a first stimulus condition to establish a first average distance between adjacent nanostructures, and
exposing the plurality of nanostructures to a second stimulus condition, different from the first stimulus condition, to establish a second average distance between adjacent nanostructures.

74. A method as in claim 59, wherein the method further comprises:
exposing the plurality of nanostructures to a first stimulus condition to establish a first average distance between adjacent nanostructures, and
establishing a flow of a fluid containing a first population of particles and a second population of particles, wherein:
the first population includes particles with maximum cross-sectional dimensions greater than the first average distance between adjacent nanostructures, and
the second population includes particles with maximum cross-sectional dimensions smaller than the first average distance between adjacent nanostructures; and
at least partially separating the first population of particles from the second and third populations of particles upon flowing the fluid through the nanostructures.

75. A method as in claim 74, wherein the fluid further comprises a third population of particles with maximum cross-sectional dimensions smaller than the particles in the second population, and the method further comprises:
exposing the plurality of nanostructures to a second stimulus condition, different from the first stimulus condition, to establish a second average distance between adjacent nanostructures that is smaller than the maximum cross-sectional dimensions of the particles in the second population and larger than the maximum cross-sectional dimensions of the particles in the third population;
establishing a flow of the fluid containing the second and third population of particles; and
at least partially separating the second population of particles from the third population of particles upon flowing the fluid through the nanostructures.

76-80. (canceled)

81. A method as in claim 72, wherein the first and second populations are substantially completely separated.

82. A method as in claim 75, wherein the second and third populations are substantially completely separated.

83. A method as in claim 59, wherein the method further comprises:
applying, to the plurality of nanostructures, a first force with a first component normal to the long axes of the nanostructures,
wherein the application of the first compressive force reduces the average distance between the nanostructures.

84. A method as in claim 59, wherein each nanostructure is positioned relative to an adjacent nanostructure at a distance so as to together define an average distance between adjacent nanostructures, and the plurality of nanostructures extends a distance at least 10 times greater than the average distance between adjacent nanostructures in each of two orthogonal directions each perpendicular to the long axes,
wherein the method further comprises:
applying, to the plurality of nanostructures, a first force with a first component normal to the long axes of the nanostructures,
wherein the application of the first compressive force reduces the average distance between the nanostructures.

85. A method as in claim 83, wherein the first force component is applied using a mechanical tool.

86. A method as in claim 83, further comprising applying a second compressive force with a second component, wherein the second component is normal to the average direction of the long axes of the nanostructures and orthogonal to the first component, and wherein the application of the second compressive force reduces the average distance between the nanostructures.

87. A method as in claim 83, wherein the average distance between the nanostructures is reduced by at least about 25%.

88-93. (canceled)

94. A method as in claim 59, further comprising adding one or more support materials to the nanostructures.

95. A method as in claim 59, further comprising:
applying a support material precursor to the plurality of nanostructures such that the support material precursor is transported between the nanostructures; and
solidifying the support material to form a nanocomposite material.

96. A method as in claim 95, wherein the support material precursor is transported between the nanostructures by capillary forces.

97. (canceled)

98. A method as in claim 95, wherein solidifying the support material comprises polymerizing the support material.

99-101. (canceled)

102. A method as in claim 59, wherein the plurality of nanostructures is arranged on a substrate and the method further comprises:
exposing the nanostructures to a chemical reagent such that the nanostructures are delaminated from the substrate.

103. A method as in claim 102, wherein exposing the nanostructures to a chemical reagent comprises exposing the nanostructures to hydrogen.

104. A method as in claim 59, further comprising the act of annealing the nanostructures.

105. A method as in claim 59, wherein the material comprises a first property along a first dimension of the material and a second, different property along a second dimension of the material.

106-115. (canceled)

116. A method as in claim 83, wherein the thickness of the assembly and the magnitude of the force are together selected to compress the nanostructures to form a device having a predetermined level of absorption of electromagnetic radiation.

117. A method as in claim 83, wherein the thickness of the assembly and the magnitude of the force are together selected such that the device absorbs at least about 90% of incident visible radiation.

118-121. (canceled)

122. A method as in claim 83, wherein the thickness of the assembly and the magnitude of the force are together selected such that the device absorbs at least about 90% of incident infrared radiation.

123-126. (canceled)
